(19) United States
(12) Patent Application Publication
(10) Pub. No.: US 2016/0315206 A1
(43) Pub. Date: Oct. 27, 2016

(54) PHOTOVOLTAIC CELL, IN PARTICULAR SOLAR CELL, AND METHOD OF PRODUCING A PHOTOVOLTAIC CELL

(71) Applicant: NTS NANO TECHNOLOGYSOLAR, Karlsruhe (DE)

(72) Inventors: Jaime LUPACA-SCHOMBER, Karlsruhe (DE); Ricardo LUPACA-SCHOMBER, Karlsruhe (DE); Joerg Andreas MERLEIN, Hamburg (DE)

(73) Assignee: NTS NANO TECHNOLOGYSOLAR, Karlsruhe (DE)

(21) Appl. No.: 15/050,795

(22) Filed: Feb. 23, 2016

Related U.S. Application Data
(63) Continuation of application No. PCT/EP2014/067450, filed on Aug. 14, 2014.

(30) Foreign Application Priority Data
Aug. 23, 2013 (DE) 102013109143.1

(51) Int. Cl. H01L 31/0216; H01L 31/056; H01L 31/18; H01L 31/0232

(52) U.S. Cl. CPC H01L 31/02168; H01L 31/02327; H01L 31/056; H01L 31/18

(57) ABSTRACT

The invention relates to a photovoltaic cell, in particular a solar cell, comprising a absorber layer which is arranged in front of an anti-reflection layer, wherein the anti-reflection layer comprises a nanostructured layer with periodically arranged antenna elements of an electrically conductive material being arranged at a distance of 1 to 50 nanometers from the absorber layer.

### CROSS REFERENCES TO RELATED APPLICATIONS

This application is a continuation of international patent application PCT/EP2014/067450, filed on Aug. 14, 2014, designating the U.S., which international patent application has been published in German language and claims priority from German patent application 10 2013 109 143.1, filed on Aug. 23, 2013. The entire content of this priority application is incorporated herein by reference.

### BACKGROUND OF THE INVENTION

The invention relates to a photovoltaic cell, in particular a solar cell, comprising an absorber layer in front of which an anti-reflection layer is located.

The invention also relates to a method of producing such a photovoltaic cell.

In the manufacture of solar cells it has been tried since years worldwide to improve the efficiency. Solar cells up to now are mostly prepared from silicon, wherein standard thick-layer solar cells normally have a thickness on the order of up to 200 micrometers and are prepared from mono-crystalline silicon. While in mono-crystalline solar cells the silicon must be of high quality and free of defects, in younger times also thin-layer solar cells with thicknesses of a few micrometers or even less are under development.

With respect to the increasing of efficiency in solar cells substantially to independent physical processes are involved:
Firstly, it is desired to couple the light optimally into the cell and to hold within the cell as long as possible, i.e. as many photons as possible shall be absorbed within the cell. Consequently, an optimized photon-management is in question.
On the other hand, the generated electrical charges (after the light absorption) must be brought from the cell to the consumer as good as possible. It is intended to minimize loss processes, i.e. an improved electron-management is in question.

Any improvement in photon-management leads directly to an increase of the number of absorbed photons within the solar cell. Thus, the better the photon-management, the higher the efficiency of the solar cell, independently of the actual electron-management within the cell.

For improving the absorption in solar cells normally an anti-reflection layer (AR-layer) is used which is structured geometrically, in particular in the form of a pyramid structure or an inverted pyramid structure. Thereby a considerable improvement in the photon-management of solar cells can be reached, and thereby the efficiency factor can be improved roughly by 10% (relatively), i.e. a solar cell having e.g. an efficiency factor of 20% for example can be improved to an efficiency factor of 22% by using an AR-layer with pyramid structure.

The AR-layer normally consists of silicon nitride and is configured as a regular pyramid structure, wherein the basis of the quadratic pyramids usually is 2 to 10 micrometers long. The tip angle of the pyramids with quadratic base surface is about 70°.

Such AR-layers in particular have the disadvantage that the structure works optimally only in a very small wavelength range of the solar spectrum.

Due to this reason it has been tried to reach an improved photon-management by plasmonic structures.

According to V. E. Ferry, J. M. Munday, H. A. Atwater, “Design Considerations for Plasmonic Photovoltaics”, Advanced Materials 2010 Adv. Mater. 2010, 22, 4794-4808 by including plasmonic nanostructures the absorption problem in particular in thin-layer cells shall be avoided. Surface plasmons are bound electromagnetic oscillations of electrons at the interface surface between a metal and a dielectric material. They can guide light and accumulate in small volumes.

A first approach for increasing solar cells by plasmonic structures thus was that nanoparticles were applied to the surface of a prior-art silicon solar cell, which is done by depositing a thin metal layer and by annealing under nitrogen, so that the structure was converted into discrete islands. However, the resulting structures were irregular. According to a second approach colloidal silver and gold nanoparticles were used as a source of dispersive elements. This led to a uniform magnitude and to a homogenous density distribution of particles at the surface. This deposition method was used with crystalline silicon, amorphous silicon and within InP/InGaAsP cells. Partially an increase in efficiency factor of 8% was found with silver nanoparticles. In addition also the effect of the magnitude and density distribution of nanoparticles of GaAs solar cells while utilizing AAO-masks (“anodic aluminum oxide”) as evaporation masks as a means for controlling the height and the density of the deposited nanoparticles was investigated. The highest increases in efficiency factor were found with dense, high arrangements of particles which was attributed to near-field coupling between the particles.

Also the effect of a nanostructured AR-layer of silver on the surface of the silicon was investigated. The nanostructured dispersive objects were ribs of 100 nanometers width and 50 nanometers height, starting from the back surface of the cell into the semiconductor. Distances of 6 micrometers as well as of 300 nanometers were investigated and herein particular absorption improvements were found.

According to H. A. Atwater and A. Polman, “Plasmonics for improved photovoltaic devices”, Nature Materials, Vol. 9, March 2010, 205-213, plasmonic solar cell structures were considered, wherein a resonant plasmonic excitation was made in thin-film solar cells while utilizing the strong near-field amplification about the metallic nanoparticles for improving the absorption of a surrounding semiconductor material. The nanoparticles then act as antennas for the incident solar light which is stored in a localized surface plasmonic mode. This shall work particularly well for small particle diameters of 5 to 20 nanometers.

For the large surface preparation of plasmonic solar cell structures the forming of metallic nanoparticles by thermal evaporation of a this metal layer was considered which was subsequently heated to form agglomerates on the surface. This led to irregularly located nanoparticles with a diameter of 100 to 150 nanometers. Using lithography with a stamp, wherein a sol-gel-mask by means of soft lithography is used with a rubber stamp, followed by a silver vapor deposit and a subsequent removal a resolution of <0.1 nanometers shall be obtained. Thereby hexagonal arrays of silver nanoparticles with a particle diameter of 300 nanometers and roughly semi-spherical shape were obtained with a distance of about 500 nanometers.

The prior art structure with optical anti-reflection layers in pyramid shape and also the newer approaches using plasmonic structures lead in part to improvements of the photon-management, however are not sufficiently developed to obtain substantial improvements.

### SUMMARY OF THE INVENTION

In view of this it is an object of the invention to disclose an improved photovoltaic cell, in particular a solar cell, by means of which a substantial improvement of the photon-management can be obtained.

It is another object of the invention to disclose an improved solar cell, by means of which a substantial improvement of the photon-management can be obtained.

It is another object of the invention to disclose an improved photovoltaic cell having an improved efficiency.

It is another object of the invention to disclose a method of making an improved photovoltaic cell having an improved efficiency.

According to the invention these and other object according to one aspect are achieved by a photovoltaic cell, comprising:
an absorber layer;
an anti-reflection layer is arranged in front of said absorber layer, said anti-reflection layer comprising:
   a nanostructured layer having periodically arranged antenna elements made of an electrically conductive material, said antenna elements being arranged at a distance of 1 to 50 nanometers from said absorber layer and being is at least partially received within said anti-reflection layer.

The object of the invention is fully solved in this way.

According to the invention when using a nanostructured layer with periodically located antenna elements of an electrically conductive material which are provided at a distance of 1 to 50 nanometers from the absorber layer, a substantial improvement of the photon-management is obtained, i.e. a substantial improvement of the absorption within the solar cell. The antenna elements can couple the total solar light spectrum (from 280 nanometers to 1100 nanometers wavelength) in a broadband manner into the solar cell and can hold the light longer within the solar cell than the prior used microstructures, since the nano antenna elements receive the absorbed light within the solar cell again and radiate back into the solar cell. In this way the light with the novel nanostructured layer can be better absorbed by a factor of 2 than with prior-art AR-layers in pyramid shape (the efficiency factor can be improved by about 20% (relatively)). In the nanostructured layer according to the invention the periodically arranged antenna elements act as surface plasmons with defined near-field characteristics.

The plasmonic structures known up to now in the prior art with nanostructured layers either do not contain periodically arranged antenna elements or are undetermined to such an extend that no optimized characteristics can be obtained for a wide range.

A particular advantage of the photovoltaic cell according to the invention rests in the fact that the nanostructured layer with periodically arranged antenna elements can be utilized with all kinds of photovoltaic cells independently from the structure of the photovoltaic cell itself.

In the photovoltaic cells according to the invention the light is collected over a larger angular range and is then radiated into the substrate, since the plasmons act as antennas. Also a blurring during irradiation with infrared light is reduced by mode forming, namely, the modes evolve in ranges of the sensor layer, whereby an improved collecting of the generated electrons is possible.

According to a preferred development of the invention the nanostructured layer together with the back-contact of the photovoltaic cell forms an optical resonator.

According to a further development of the invention a nanostructured layer is arranged at a distance of 2 to 20 nanometers from the absorber layer, preferably at a distance of 5 to 15 nanometers, particularly preferred at a distance of 7 to 12 nanometers.

It has been found that with such a distance particularly good characteristics, in particular a particularly good absorption improvement, can be obtained over a wide wavelength range.

Preferably the antenna elements are arranged at distances of 200 to 800 nanometers, preferably of 250 to 750 nanometers, periodically with respect to each other. The individual antenna elements herein preferably are arranged periodically, either orthogonally or hexagonally with respect to each other.

The height of the antenna elements preferably is 10 to 200 nanometers, more preferred 20 to 150 nanometers, particularly preferred 30 to 120 nanometers.

The maximum extension of the antenna elements in lateral direction preferably is 20 to 400 nanometers, more preferred 40 to 250 nanometers, particularly preferred 100 to 250 nanometers.

The minimum extension of the antenna elements in lateral direction preferably is 25 nanometers, more preferred 30 nanometers, particularly preferred at least 50 nanometers.

With such a dimensioning particularly advantageous characteristics can in particular be mated to particular cell structures over a wide range, to obtain an improved absorption over a particular frequency spectrum overall, or to possibly amplify particular frequency ranges so that also the utilization of photovoltaic cells in the field of optical sensors is possible.

The nanostructured layer with the antenna elements is preferably at least partially received within the anti-reflection layer which, preferably, consists of SiOₓN_{y} (for example SiO₃N₄), titanium oxide or ITO (“Indium Tin Oxide”). As far as a nanostructured layer due to its height partially protrudes beyond the anti-reflection layer, it preferably lies within a protection layer applied thereabove which may for instance consist of silicon oxide.

The nanostructured layer may consist of identical antenna elements or of antenna elements of different shapes and/or magnitudes which are combined with each other in a regular pattern.

According to a further development of the invention the nanostructured layer consists of circular, polygonal, triangular or quadratic antenna elements, of cross-shaped antenna elements in the form of rods crossed to each other in symmetric design, in the shape of a square with smaller attached squares at each outer side in symmetric configuration, in the shape of a square with quadratic recesses at each corner region in symmetric configuration, or in the shape of a circle with four tangentially attached rectangles in symmetric configuration, wherein the rectangles either are arranged in the direction of an unit cell or are offset by 45°, or consist of star-shaped elements comprising six tips which are arranged hexagonally on a unit cell, wherein the tips respectively of the star-shaped antenna elements point towards each other or the sides between the tips point towards each other.

With such antenna elements the dependency of the particular application, i.e. in particular an absorption improvement with a particular solar cell, or a specific amplification of a particular frequency range, or a filtering of a particular frequency range can be reached when used as a sensor.

Preferably, such antenna elements are configured as cylinders or as straight prisms, which extend perpendicularly to a main direction of extension of the photovoltaic cell.

Further preferred the antenna elements consist of a metal which is selected from the group consisting of silver, copper, aluminum, gold, and alloys thereof.

In most cases silver is particularly preferred, however for particular applications also other metals may be advantageous.

According to a further development of the invention the antenna elements consist of a metal which is selected from the group consisting of silver, copper, aluminum, gold and alloys thereof, and wherein at least one side of the antenna elements facing the absorber or facing away from the absorber is coated with a different material which is selected from the group consisting of silver, copper, aluminum, gold, and alloys thereof.

By such a coating the antenna elements on one side or on the other side or on both sides, specifically improved characteristics can be reached.

According to a further development of the invention the nanostructured layer consists of straight cylinders. This is particularly advantageous, when the photovoltaic cell is configured as a solar cell, in particular a silicon solar cell.

It has been found that the design of the nanostructured layer with straight cylinders leads to a particularly good absorption increase over the total spectral range of solar light.

According to a further development of this configuration the nanostructured layer consists of cylinders with a diameter of 150 to 250 nanometers, preferably of 180 to 200 nanometers, and of a height of 50 to 90 nanometers, which preferably are arranged in an orthogonal pattern at a distance of 400 to 600 nanometers, preferably of 450 to 510 nanometers and having a distance to the absorber layer of 5 to 13 nanometers, preferably of 8 to 10 nanometers.

Thereby optimized characteristics are obtained for standard solar cells, i.e. mono-crystalline solar cells, of a thickness of about 180 to 200 micrometers.

According to a further preferred development of the invention the solar cell is configured as a standard thick-layer solar cell of a thickness of up to 200 micrometers, wherein the cylinders of the nanostructured layer have a diameter of 185 to 195 nanometers, preferably of about 190 nanometers, a height of 68 to 72 nanometers, preferably of about 70 nanometers, are arranged in an orthogonal pattern at a distance to the absorber layer of 8.5 to 9.5 nanometers, preferably of about 9 nanometers, and at a distance of 460 to 470 nanometers with respect to each other, preferably of about 465 nanometers.

Thereby optimized conditions for a standard thick-layer solar cell are obtained.

According to a further development of the invention the solar cell is configured as a HIT-thick-layer solar cell of a thickness of up to 200 micrometers, wherein the cylinders of the nanostructured layer have a diameter of about 185 to 195 nanometers, preferably of about 190 nanometers, a height of 68 to 72 nanometers, preferably of about 70 nanometers, a distance to the absorber layer of 8.5 to 9.5 nanometers, preferably of about 9 nanometers and are arranged at a distance of 485 to 495 nanometers, preferably of about 490 nanometers, within an orthogonal pattern with respect to each other. Thereby optimal characteristics for a Hit-thick-layer solar cell (“hetero junction with intrinsic thin layer”—HIT) are obtained.

With an ultra-thin layer solar cell the nanostructured layer advantageously consists of cylinders with a diameter of 200 to 300 nanometers, preferably of about 250 nanometers, with a height of 50 to 90 nanometers, preferably of about 70 nanometers which preferably are arranged in an orthogonal pattern at a distance of 400 to 600 nanometers, preferably of about 525 nanometers and at a distance to the absorber layer of 5 to 13 nanometers, preferably of about 9 nanometers.

Thereby ideal conditions with respect to an ultra-thin layer solar cell are obtained.

The ultra-thin-layer solar cell may for instance be a cell having a thickness in the range of about up to 1000 nanometers, for instance with a back contact layer of silver and a thickness of 200 nanometers, with an absorber layer of silicon with a thickness of about 150 nanometers, an AR-layer for instance of silicon nitride with a thickness of about 45 nanometers, and with a protection layer of silicon dioxide with a thickness of about 64 nanometers.

According to a further configuration of the invention the photovoltaic cell is utilized as a solar cell having an absorption increase of selected frequency ranges of incident radiation.

Also in particular depending on the thickness of the solar cell an absorption increase with respect to selected frequency ranges of incident radiation can be obtained for possibly utilizing infrared parts increasingly which are partially unused, so that overall a uniform utilization of the radiation over the total frequency band of the incident light results.

According to a further development of the invention the photovoltaic cell is used as a sensor including an absorption increase of selected frequency ranges and/or an optical signal attenuation over a particular frequency range.

Depending on the selected parameters of the nanostructured layer the characteristics can be varied in large limits to obtain particular absorption increases of selected frequency ranges, such as for instance to effect particular amplifications of individual frequency ranges. Conversely, also optical signal attenuations can be obtained over a particular frequency range, i.e. optical filter functions.

A photovoltaic cell according to the invention can be produced advantageously by producing the photovoltaic cell with an absorber and an anti-reflection layer (unstructured) thereabove, wherein the anti-reflection layer with a nanostructured layer of periodically arranged antenna elements of an electrically conductive material is prepared with a distance of 1 to 50 nanometers to the absorber surface.

Herein preferably at least a shape, magnitude, arrangement, periodicity, and distance of the antenna elements from the absorber surface are adapted depending from the structure and the design parameters of the photovoltaic cell to obtain a specific absorption increase within a desired first frequency range and/or an optical signal attenuation over a second frequency range.

By adjusting the antenna elements thus the characteristics of the nanostructured layer can be particularly tailored with respect to the desired application.

A preparation of the nanostructured layer basically is done using known processes which are adapted with respect to the desired application.

According to another aspect of the invention a method of producing a photovoltaic cell is disclosed, wherein said photovoltaic cell is made with an absorber and an anti-reflection layer arranged there above, wherein said anti-reflection layer is prepared with a nanostructured layer with periodically arranged antenna elements of an electrically conductive material with a distance of 1 to 50 nanometers to said absorber surface.

According to a further aspect of the invention the nanostructured layer is prepared including at least the following steps:
Applying a photoresist layer onto the protective layer;
embossing the photoresist layer by means of a nanostructured stamp;
developing the photoresist layer by means of irradiating with UV light for generating a nanostructured photoresist layer;
etching for generating recesses;
two-dimensional coating of the nanostructured layer with an electrically conductive material;
removing the photoresist layer.

Herein the preparation of the nanostructured layer is a nano-imprinting process, namely the so-called nano-imprinting lithography. Herein a soft embossing stamp is utilized at room temperature. The contact force is smaller than 1000 newtons. When developing the photoresist layer UV-light of a wavelength range of 350 to 450 nanometers is used. Resolutions of <15 nanometers can be obtained, and substrates of 10 to 200 mm can be processed. It is the so-called UV-nano-imprint-lithography (UV-NIL).

Alternatively, also the so-called nano-interference-lithography can be utilized for generating the patterning of the photoresist layer.

The remaining steps correspond to the steps mentioned above, namely:
Etching for generating recesses within the anti-reflection layer;
two-dimensional coating of the nanostructured layer by means of an electrically conductive material;
removing the photoresist layer.

Basically the generation of the nanostructured layer advantageously is performed on fully processed solar cells at which, however, the anti-reflection layer was prepared unstructured, i.e. as a continuous layer without a pyramid structure.

In this way the known manufacturing processes in the manufacturing of solar cells must not be altered. The nanostructured layer thus can also be generated subsequently and can thereafter again be sealed applying a protective layer which preferably consists of silicon dioxide.

In this way the production of the nanostructured layer can be adjusted easily to the production processes already known.

It will be understood that the afore-mentioned features of the invention and the features to be described hereinafter cannot only be utilized in the given combination, but also in different combinations or independently, without leaving the scope of the invention.

### BRIEF DESCRIPTION OF THE DRAWINGS

Further features and advantages of the invention can be taken from the subsequent description of preferred embodiments with reference to the drawings. In the drawings show:

FIG. 1 a simplified cross section of a solar cell according to the invention;

FIGS. 2a to 2c different steps in performing the UV-nano-lithography process for generating the nanostructured layer;

FIGS. 3a to 3s different configurations and spatial arrangements of the antenna elements;

FIGS. 4a to 4l a summary of different simulation results for computing the absorption increase depending from the wavelength in selected configurations of antenna elements, showing the amplification factor g over the wavelength (μm); wherein

FIGS. 4a (1) to (7) relating to FIG. 3l (series 11, see table 1):

FIG. 4a (1) showing maxima at about 925 nm with an amplification factor of about 2.6;

FIG. 4a (2) showing maxima at about 1075 nm with an amplification factor of about 2.8;

FIG. 4a (3) showing maxima at about 1075 nm with an amplification factor of about 4.0;

FIG. 4a (4) showing maxima at about 1075 nm with an amplification factor of about 4.9;

FIG. 4a (5) showing maxima at about 1075 nm with an amplification factor of about 5.5;

FIG. 4a (6) showing maxima at about 1075 nm with an amplification factor of about 6.1;

FIG. 4a (7) showing maxima at about 1075 nm with an amplification factor of about 6.6;

FIGS. 4b (1) to (3) relating to FIG. 3m (series 12, see table 1):

FIG. 4b (1) showing maxima at about 1075 nm with an amplification factor of about 7.5;

FIG. 4b (2) showing maxima at about 1075 nm with an amplification factor of about 12.5;

FIG. 4b (3) showing maxima at about 1075 nm with an amplification factor of about 16.0;

FIGS. 4b (4) to (7) relating to FIG. 3n (series 13, see table 1:

FIG. 4b (4) showing maxima at about 875 nm with an amplification factor of about 6.0;

FIG. 4b (5) showing maxima at about 1075 nm with an amplification factor of about 6.0;

FIG. 4b (6) showing maxima at about 1075 nm with an amplification factor of about 16.0;

FIGS. 4c (1) to (6) relating to FIG. 3o (series 14, cross with circle and rectangle, see table 1);

FIG. 4c (1) showing maxima at about 1050 nm with an amplification factor of about 3.0;

FIG. 4c (2) showing maxima at about 875 nm with an amplification factor of about 4.2;

FIG. 4c (3) showing maxima at about 875 nm with an amplification factor of about 6.1;

FIG. 4c (4) showing maxima at about 875 nm with an amplification factor of about 8.3;

FIG. 4c (5) showing maxima at about 875 nm with an amplification factor of about 8.2;

FIG. 4c (6) showing maxima at about 875 nm with an amplification factor of about 6.5;

FIGS. 4d (1) to (6) relating to FIG. 3p (series 14, cross with circle and rectangle, rectangle rotated by 45° with respect to FIG. 3p, see table 1):

FIG. 4d (1) showing maxima at about 700 nm with an amplification factor of about 2.1;

FIG. 4d (2) showing maxima at about 700 nm with an amplification factor of about 1.9;

FIG. 4d (3) showing maxima at about 690 nm with an amplification factor of about 1.9;

FIG. 4d (4) showing maxima at about 690 nm with an amplification factor of about 2.9;

FIG. 4d (5) showing maxima at about 750 nm with an amplification factor of about 3.6;

FIG. 4d (6) showing maxima at about 750 nm with an amplification factor of about 4.0;

FIGS. 4e (1) to (6) relating to FIG. 3r (series 17, see table 1):

FIG. 4e (1) showing maxima at about 900 nm with an amplification factor of about 4.2;

FIG. 4e (2) showing maxima at about 1050 nm with an amplification factor of about 11.5;

FIG. 4e (3) showing maxima at about 1050 nm with an amplification factor of about 16.0;

FIG. 4e (4) showing maxima at about 1050 nm with an amplification factor of about 17.0;

FIG. 4e (5) showing maxima at about 1050 nm with an amplification factor of about 18.0;

FIG. 4e (6) showing maxima at about 1050 nm with an amplification factor of about 19.0;

FIG. 4f (1) to FIG. 4f (2) relating FIG. 3g (series 6, see table 1):

FIG. 4f (1) showing maxima at about 875 nm with an amplification factor of about 2.4;

FIG. 4f (2) showing maxima at about 875 nm with an amplification factor of about 1.7;

FIG. 4f (3) relating FIG. 3h (series 7, see table 1), showing maxima at about 825 nm with an amplification factor of about 2.1;

FIG. 4g (1) to FIG. 4 g (3) relating to FIG. 3g (series 6, see table 1):

FIG. 4g (1) showing maxima at about 750 nm with an amplification factor of about 1.4;

FIG. 4g (2) showing maxima at about 1075 nm with an amplification factor of about 3.2;

FIG. 4g (3) showing minimum at about 920 nm with an amplification factor of about 0.17;

FIG. 4h (1) to FIG. 4 h (6), FIG. 4i (1) to FIG. 4i (5), FIG. 4j (1) to FIG. 4j (6), FIG. 4k (1) to FIG. 4k (6), and FIG. 4l (1) to FIG. 4l (5) all relate to FIG. 3i (series 8, see Table 1);

FIG. 4h (1) showing maxima at about 1100 nm with an amplification factor of about 6.0;

FIG. 4h (2) showing maxima at about 1100 nm with an amplification factor of about 6.2;

FIG. 4h (3) showing maxima at about 1100 nm with an amplification factor of about 4.5;

FIG. 4h (4) showing maxima at about 1100 nm with an amplification factor of about 4.4;

FIG. 4h (5) showing maxima at about 1100 nm with an amplification factor of about 5.0;

FIG. 4h (6) showing maxima at about 1100 nm with an amplification factor of about 5.5;

FIG. 4i (1) showing maxima at about 825 nm with an amplification factor of about 7.1;

FIG. 4i (2) showing maxima at about 1100 nm with an amplification factor of about 4.8;

FIG. 4i (3) showing maxima at about 1100 nm with an amplification factor of about 5.5;

FIG. 4i (4) showing maxima at about 825 nm with an amplification factor of about 6.0;

FIG. 4i (5) showing maxima at about 1100 nm with an amplification factor of about 6.5;

FIG. 4j (1) showing maxima at about 1100 nm with an amplification factor of about 7.0;

FIG. 4j (2) showing maxima at about 1100 nm with an amplification factor of about 7.2;

FIG. 4j (3) showing maxima at about 1100 nm with an amplification factor of about 6.1;

FIG. 4j (4) showing maxima at about 1100 nm with an amplification factor of about 6.8;

FIG. 4j (5) showing maxima at about 1100 nm with an amplification factor of about 6.2;

FIG. 4j (6) showing maxima at about 850 nm with an amplification factor of about 4.8;

FIG. 4k (1) showing maxima at about 1100 nm with an amplification factor of about 5.0;

FIG. 4k (2) showing maxima at about 850 nm with an amplification factor of about 4.8;

FIG. 4k (3) showing maxima at about 1100 nm with an amplification factor of about 4.9;

FIG. 4k (4) showing maxima at about 850 nm with an amplification factor of about 4.8;

FIG. 4k (5) showing maxima at about 825 nm with an amplification factor of about 4.8;

FIG. 4k (6) showing maxima at about 850 nm with an amplification factor of about 4.7;

FIG. 4l (1) showing maxima at about 1100 nm with an amplification factor of about 4.5;

FIG. 4l (2) showing maxima at about 1100 nm with an amplification factor of about 4.6;

FIG. 4l (3) showing maxima at about 1100 nm with an amplification factor of about 4.7;

FIG. 4l (4) showing maxima at about 1100 nm with an amplification factor of about 4.8;

FIG. 4l (5) showing maxima at about 1100 nm with an amplification factor of about 4.6.

### DESCRIPTION OF PREFERRED EMBODIMENTS

In FIG. 1 a photovoltaic cell which here is configured as a solar cell, is depicted in total with numeral 10. This is for instance a standard thick-layer solar cell of (mono-crystalline) silicon comprising an absorption layer 12, a back contact layer 14 of silver, a front side anti-reflection layer 16 of silicon nitride (Si₃N₄) and thereabove a protective layer of silicon dioxide. In addition a nanostructured layer 20 including antenna elements 22 is partially received within the AR-layer 16 and partially protrudes into the protective layer 18. The nanostructured layer 20 has a height h and a distance d from the absorber layer 12.

The individual antenna elements may for instance consist of silver, but also of a different material, such as copper, aluminum, gold or alloys thereof, respectively and may possibly on the side of the AR-layer 16 or on the remote side be coated with a different material, may e.g. consist of silver and may be coated on the AR-side with gold. The shape, magnitude, arrangement and further parameters of the antenna elements 22 can be varied in wide limits to generate tailored characteristics of the nanostructured layer with respect to the respective application. The antenna elements 22 together with the back contact 14 form an optical resonator, wherein the antenna elements 22 act as plasmons.

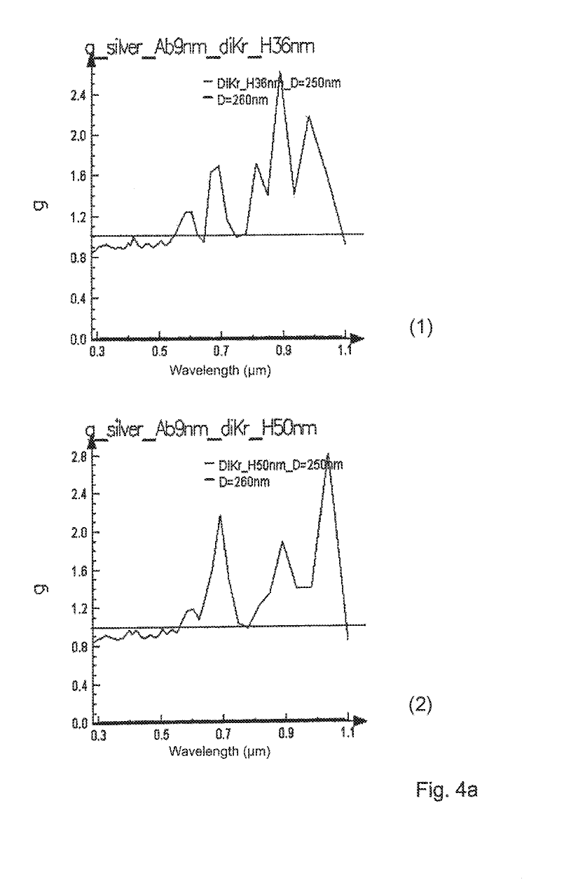

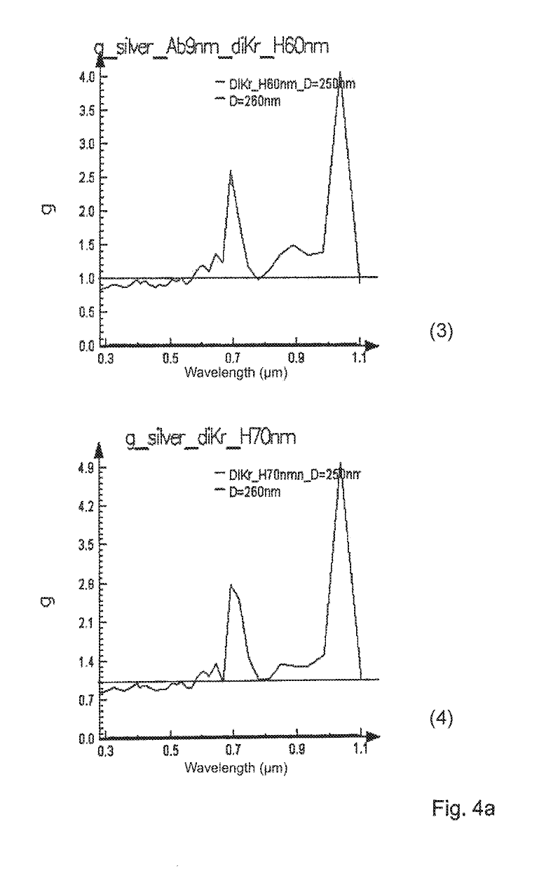

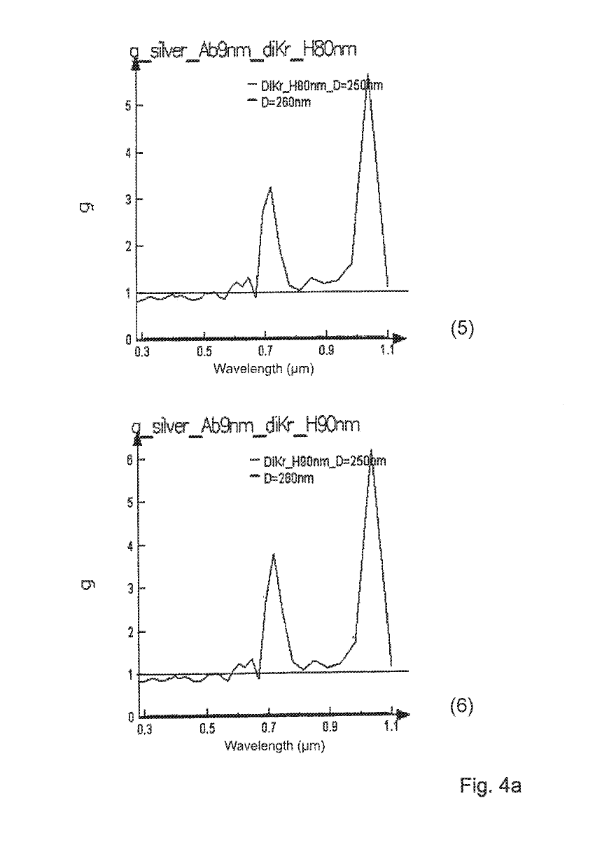

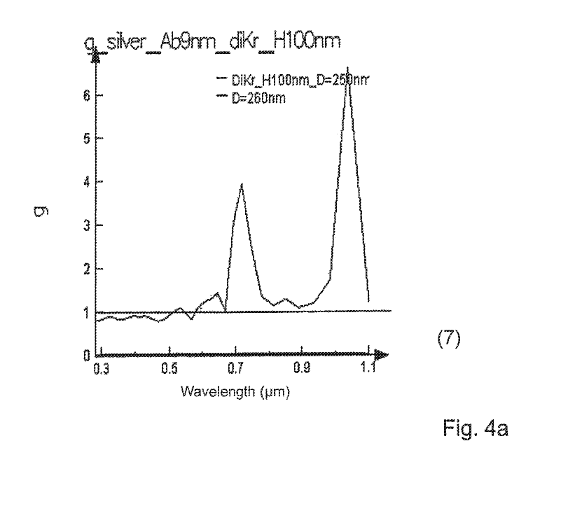

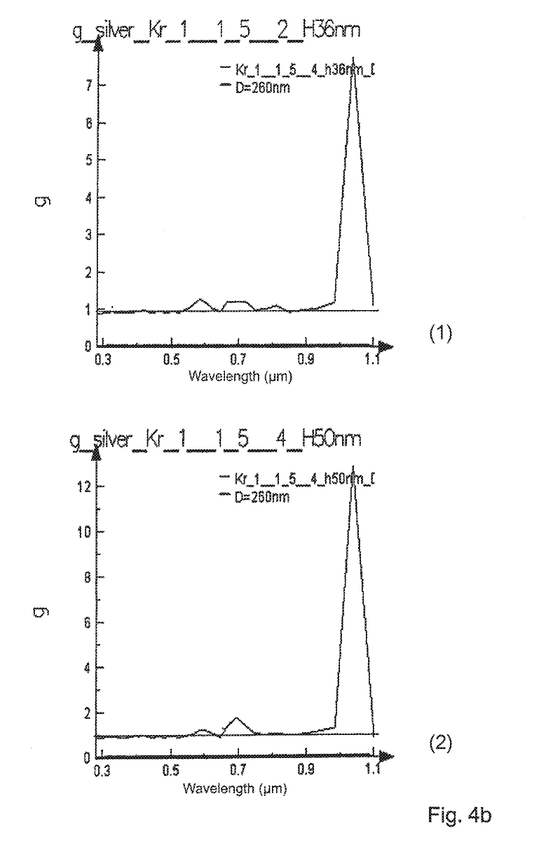

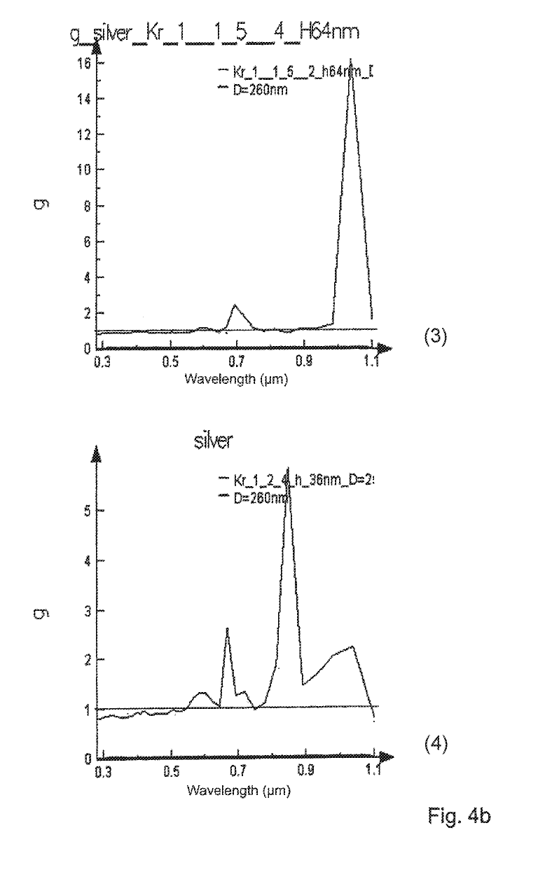

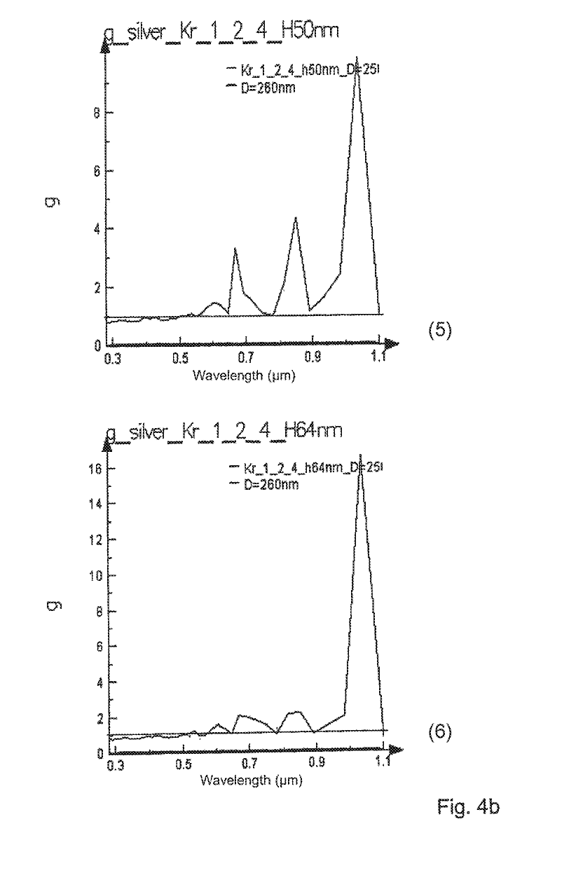

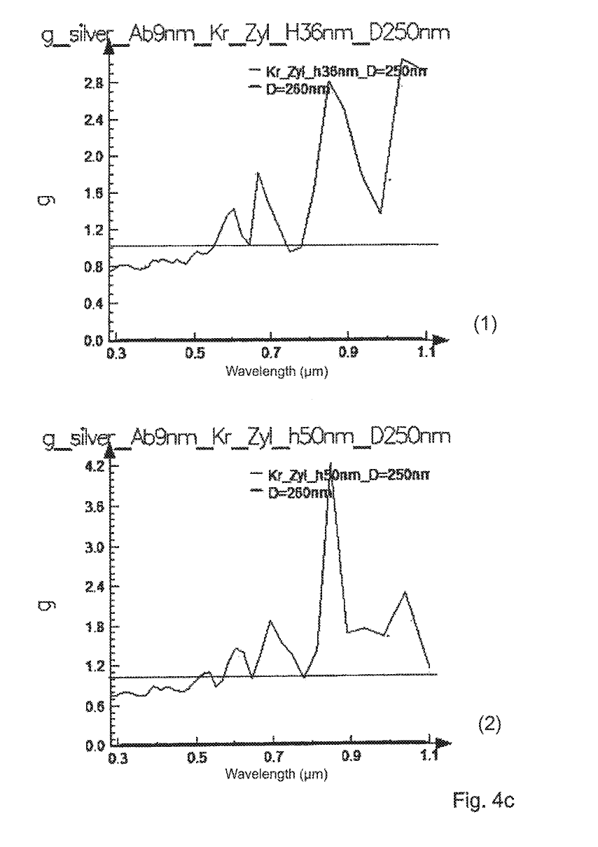

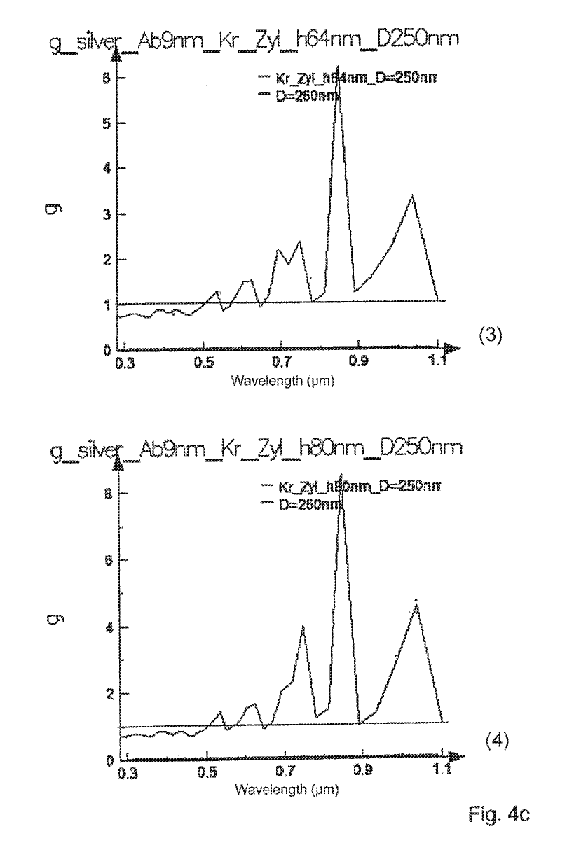

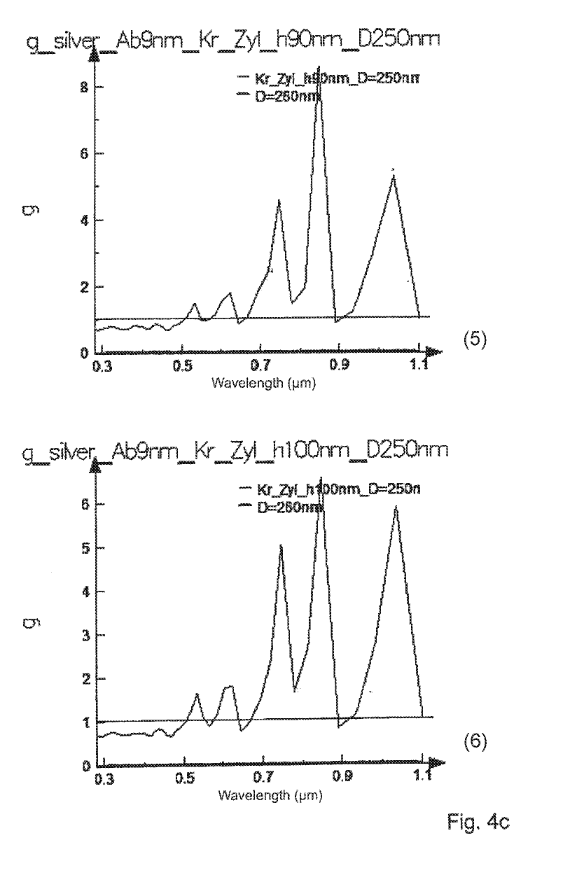

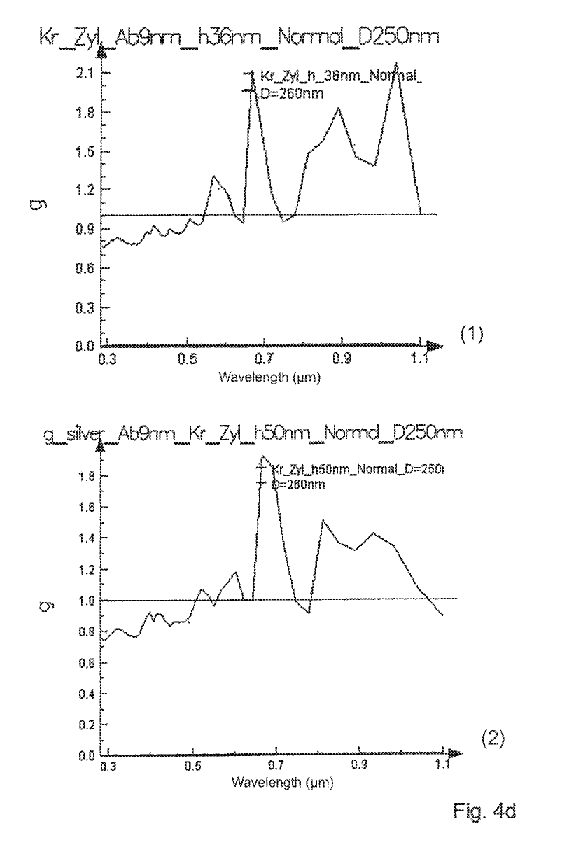

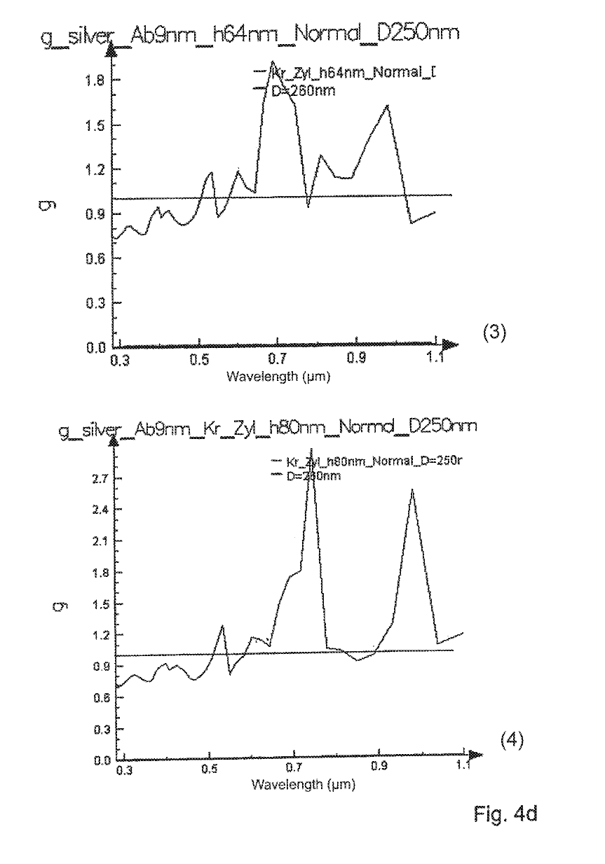

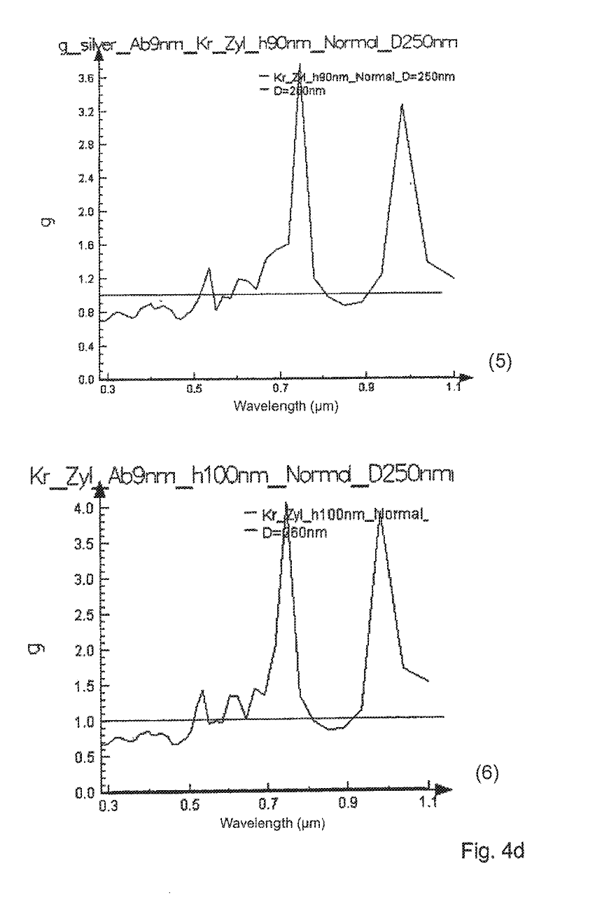

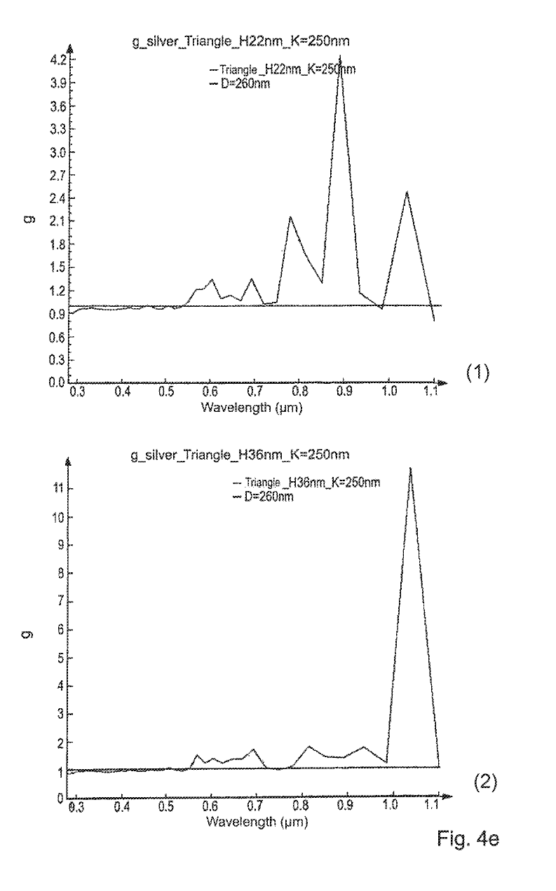

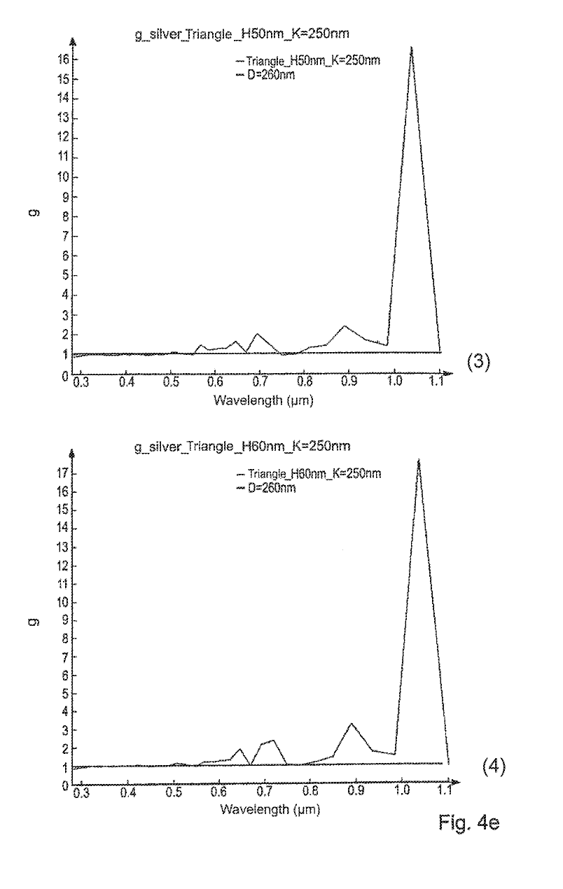

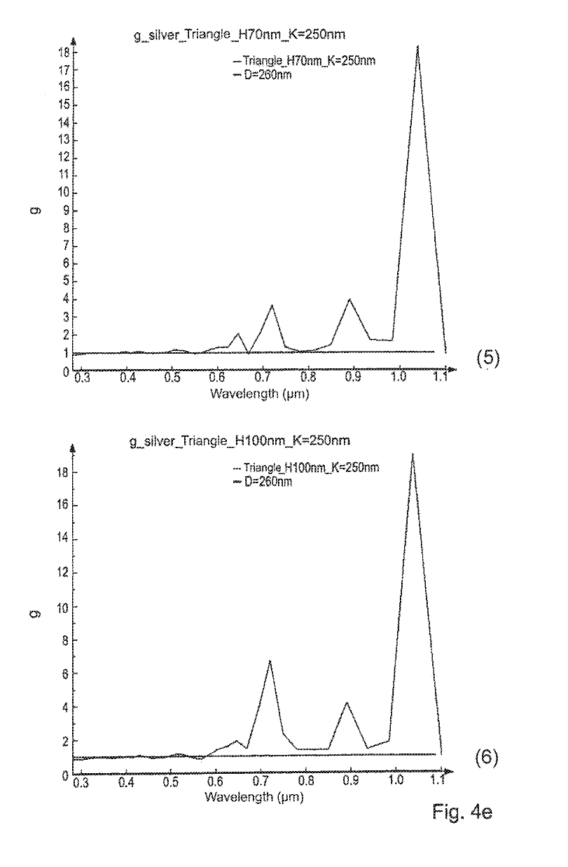

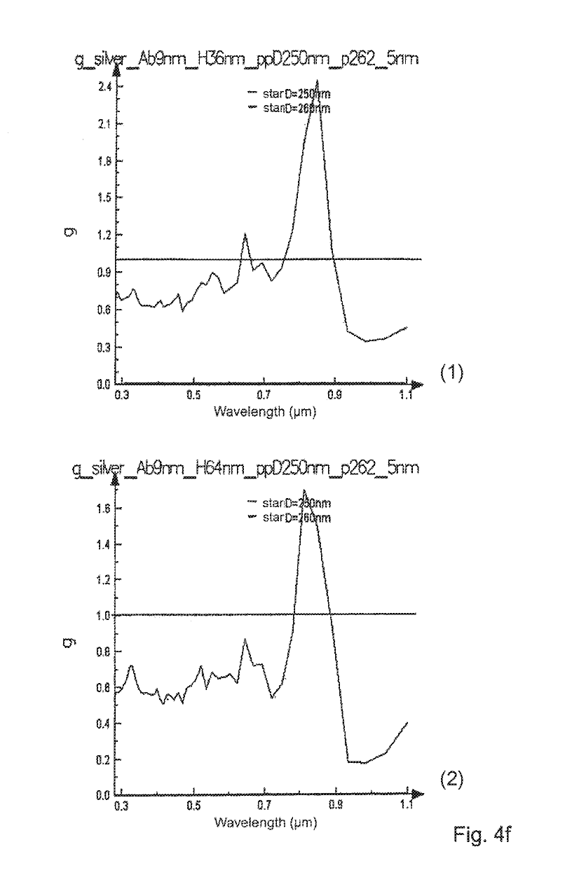

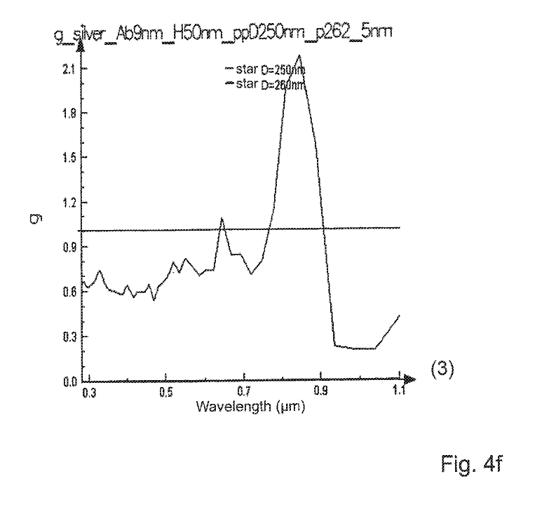

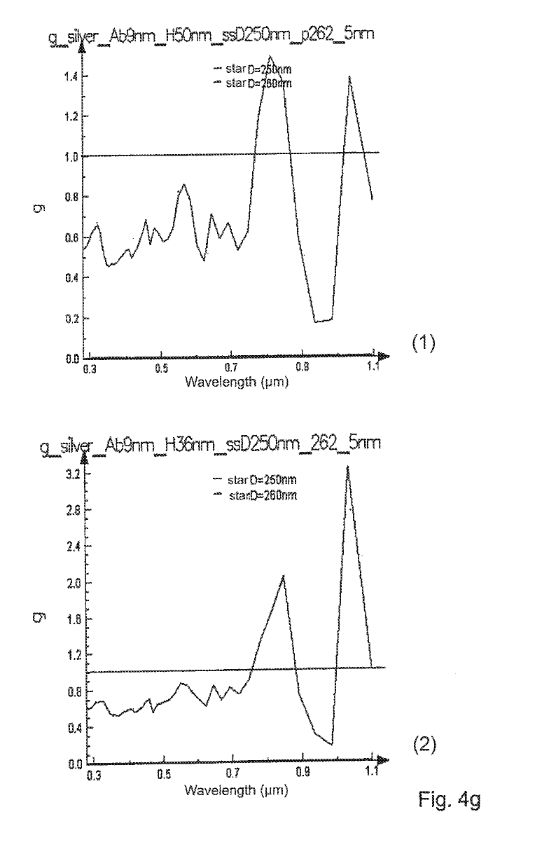

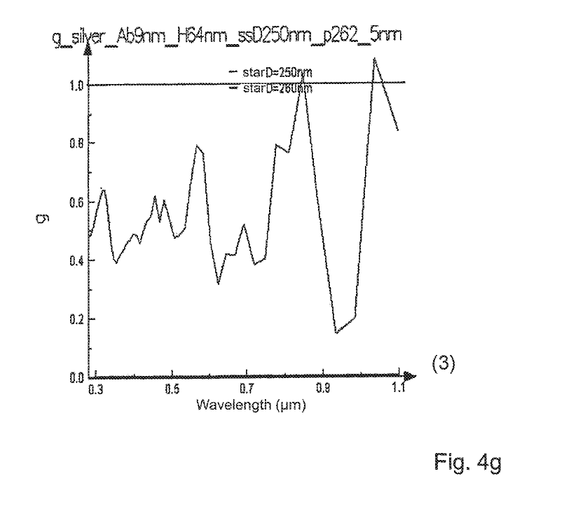

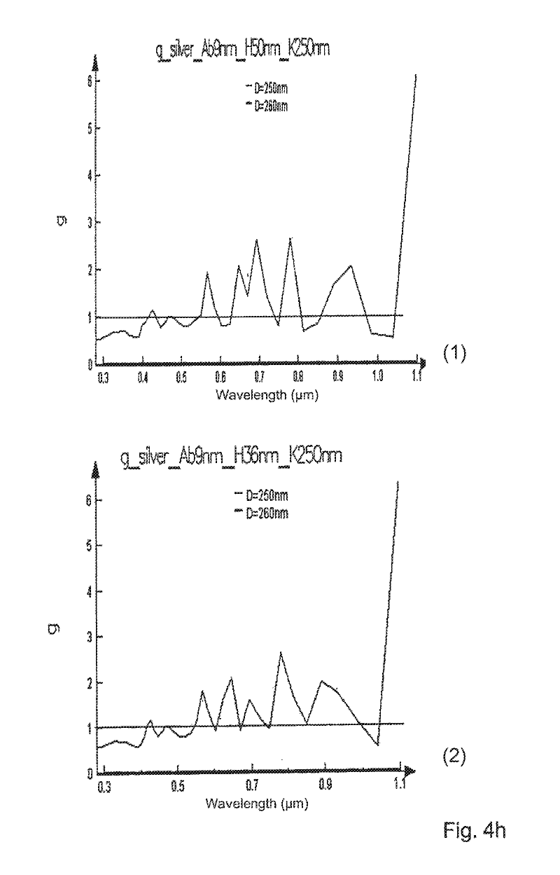

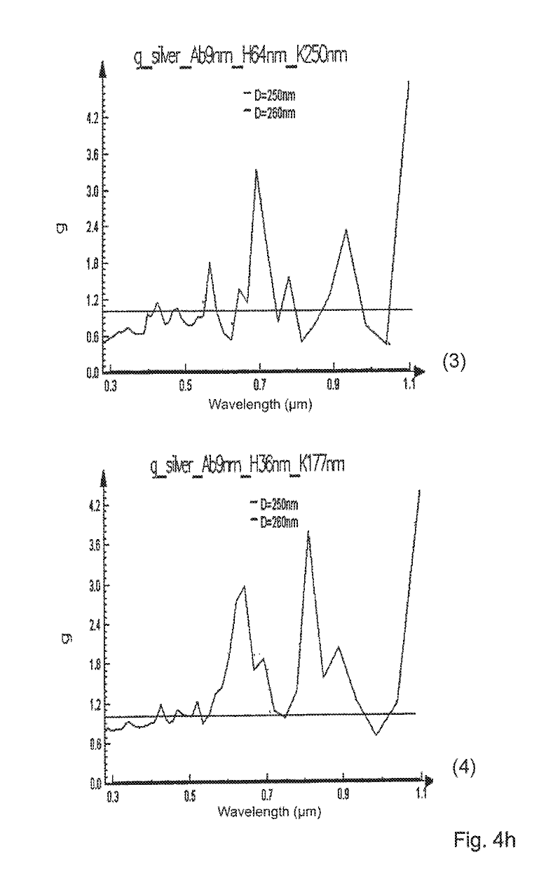

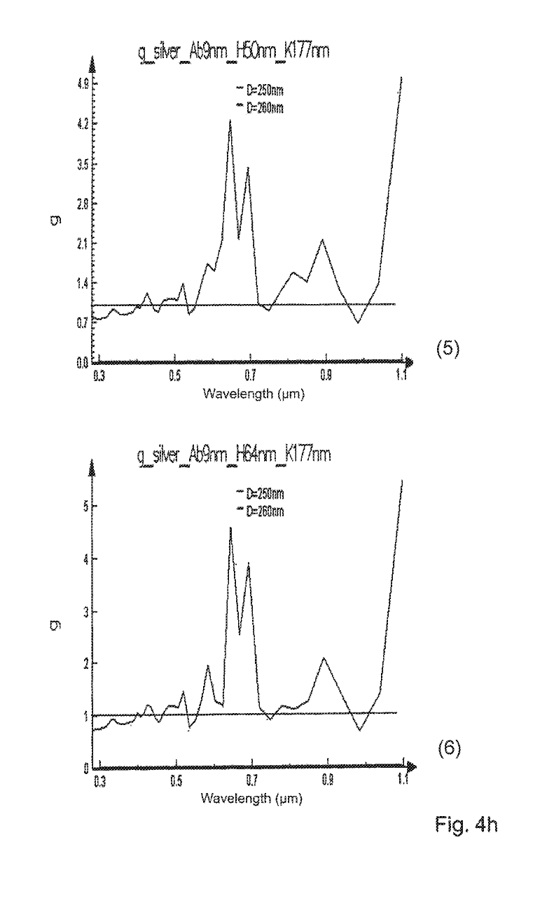

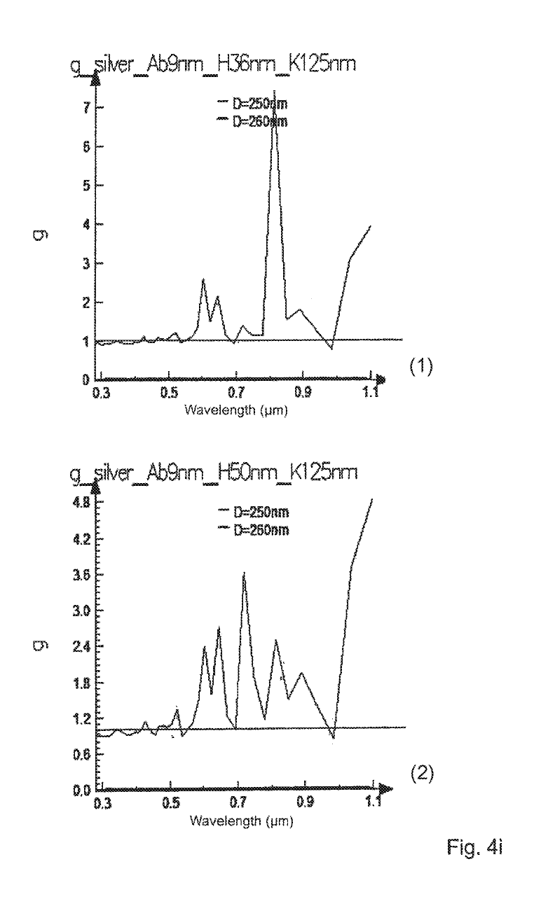

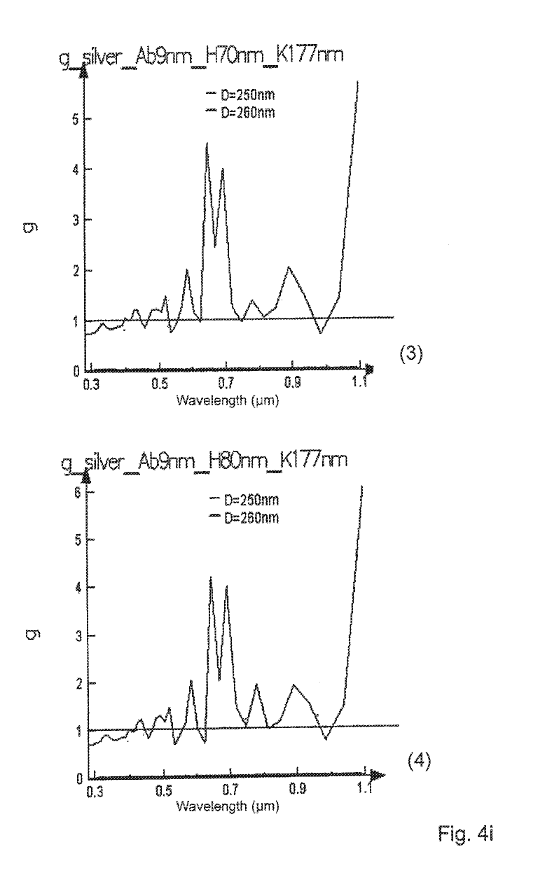

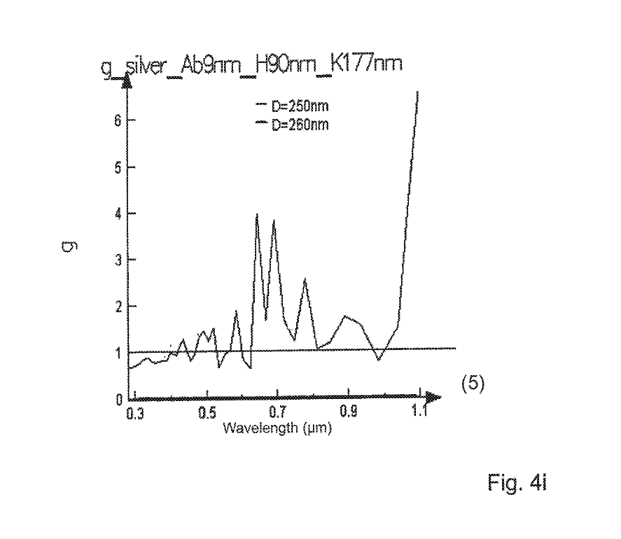

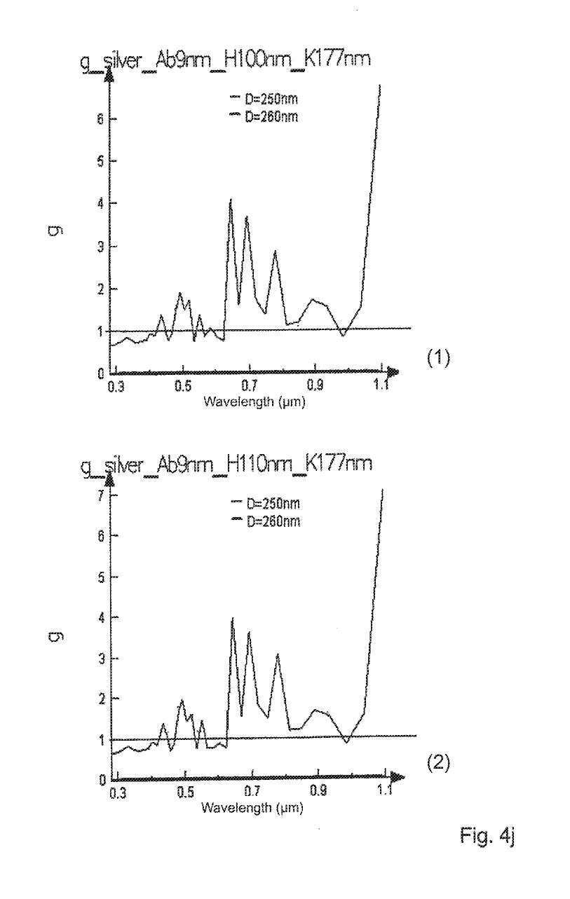

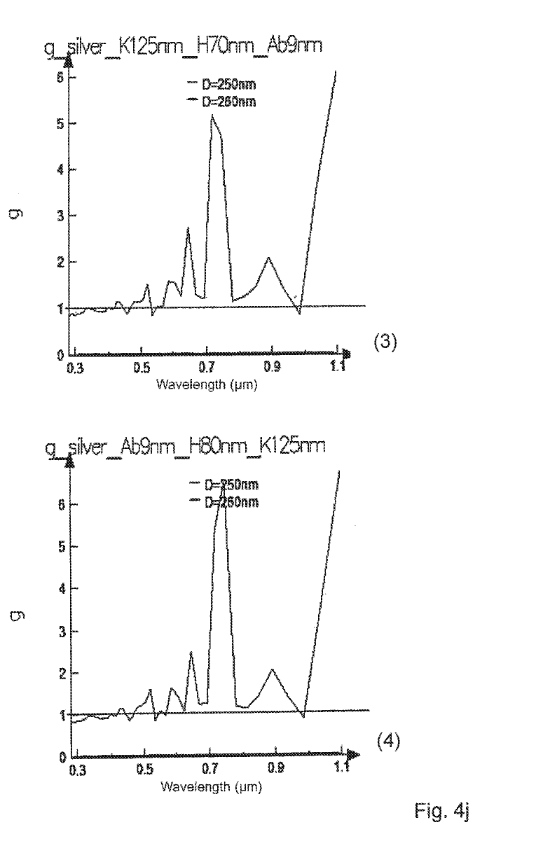

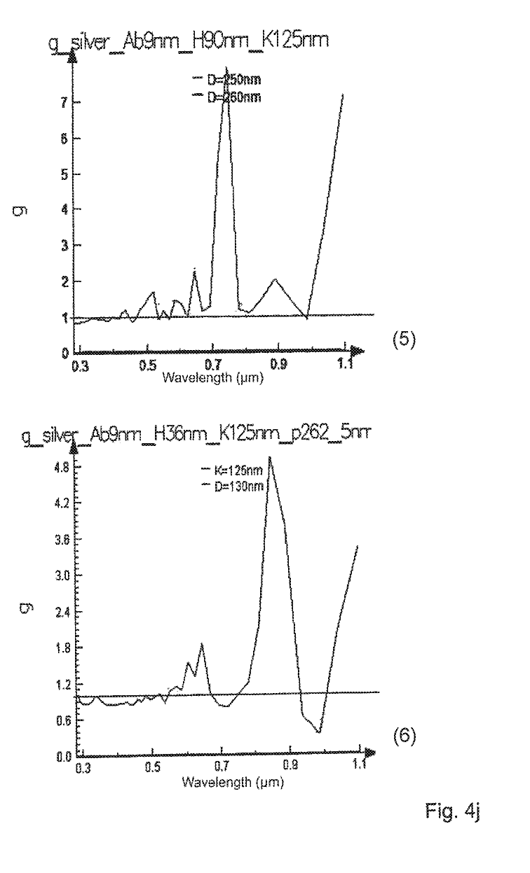

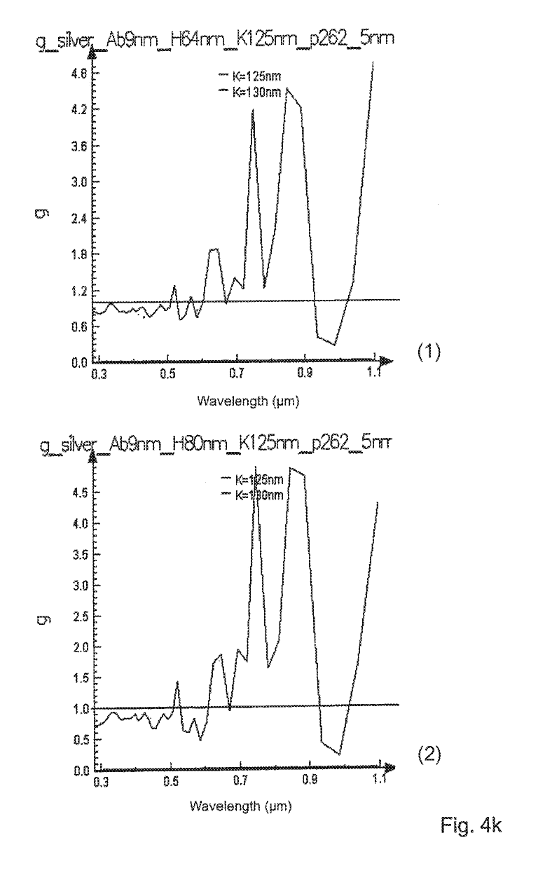

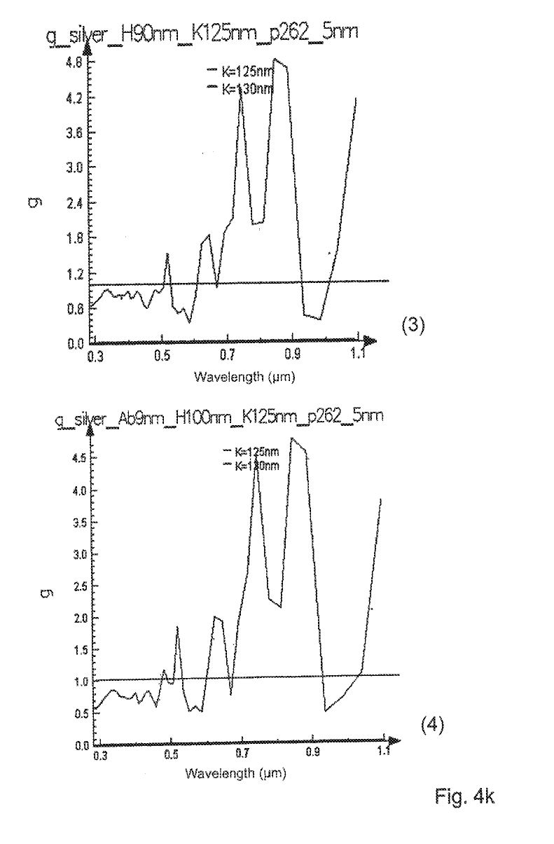

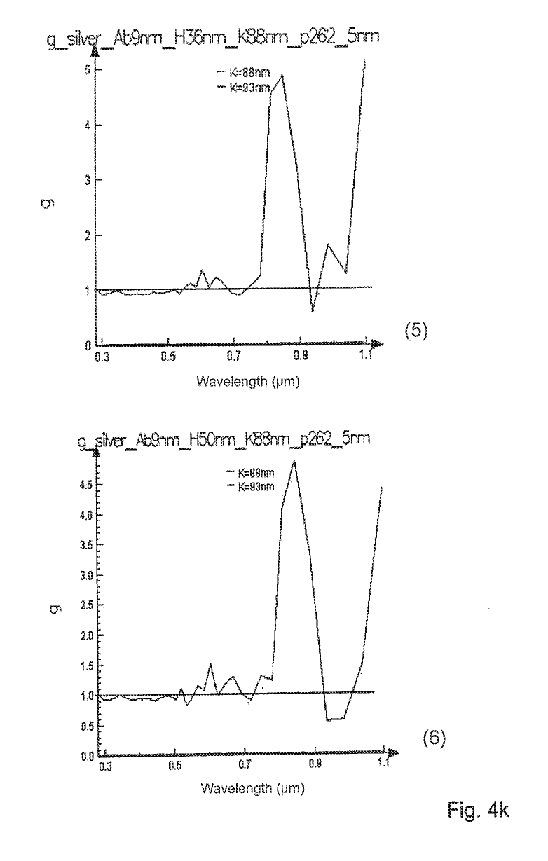

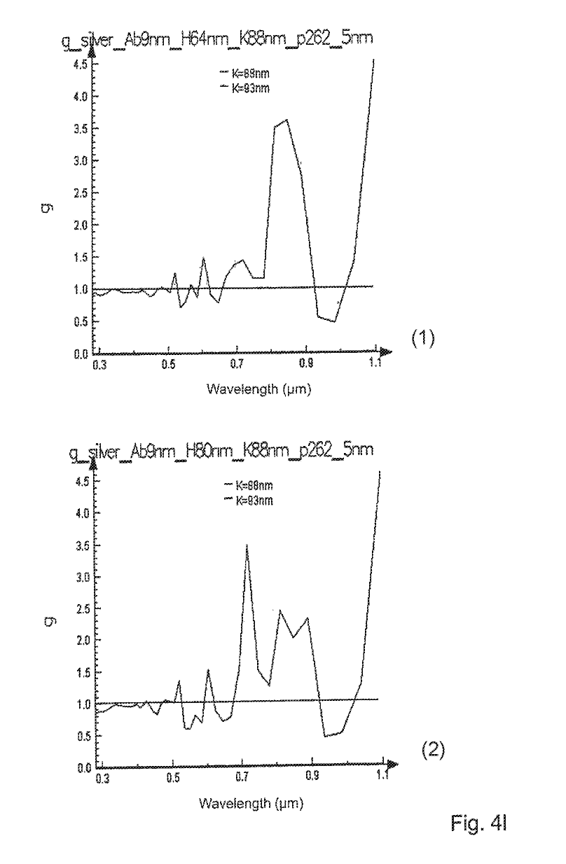

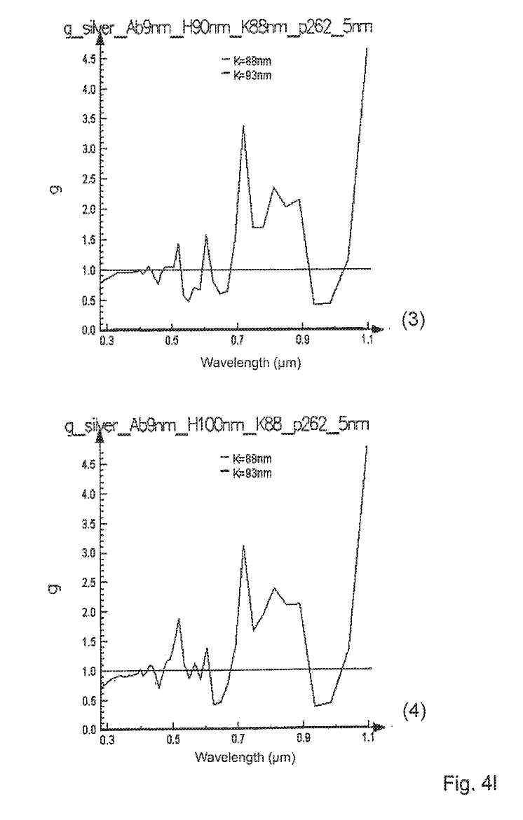

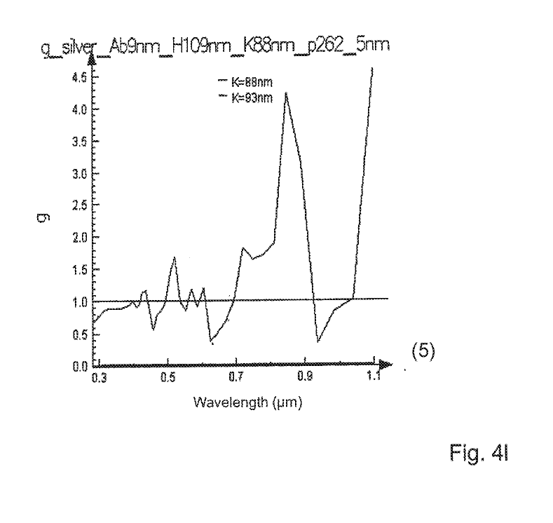

By simulating the various parameters an optimal set of design parameters can be determined for the respective application case. Herein the absorption increase in dependence of the wavelength can be computed by simulation which is defined as g (λ)=absorption with nanostructured layer/absorption without nanostructured layer. As long as the factor g>1, by means of the nanostructured layer thus an improvement of the absorption results. Such simulation results are shown exemplarily in FIGS. 4a to 4e which are explained hereinafter.

Basically the preparation of the nanostructured layer 20 is done using processes known in the prior art which are adjusted to the respective procedure. Preferably herein the photovoltaic cell or solar cell, respectively, is completely prepared according to processes known in the prior art, and only subsequently the nanostructured layer is applied. Only the anti-reflection layer (AR-layer) 16 is generated as a two-dimensional layer and is not structured as a pyramid pattern as known in the prior art.

The advantage of a subsequent generation of the nanostructured layer 20 rests in the fact that die photovoltaic cell can be fully processed according to known processes so that no process alterations are necessary.

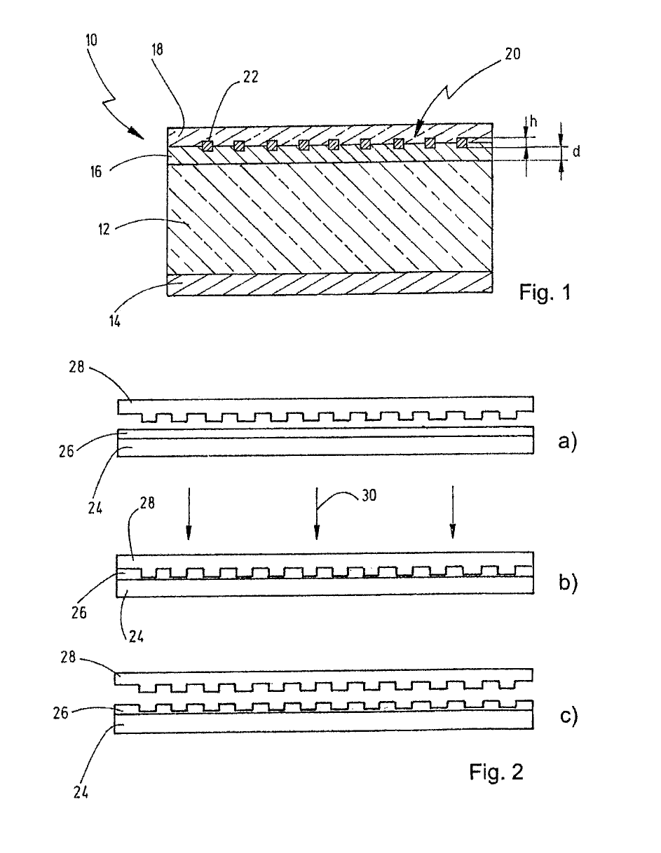

The preparation of the nanostructured layer 20 according to the UV-NIL process in the following is shortly explained with reference to FIG. 2.

Herein first the solar cell is prepared, as known in the prior art and as explained above, however with a two-dimensional AR-layer 16. Thereafter onto the protective layer 18 a photoresist layer is applied, for instance by spin coating. A substrate 24 with a photoresist layer 26 according to FIG. 2(a) results. The substrate 24 in this case is the protective layer 18 of the solar cell 10 (it is also conceivable to begin directly after the application of the AR-layer 16 before the application of the protective layer 18). The photoresist layer 26 is subsequently patterned by means of a stamp 28 having the pattern of the nanostructured layer 20. The soft stamp 28 consisting of rubber according to FIG. 2(b) is impressed at room temperature with a contact force of <1000 newtons, as indicated by the arrows 30 in FIG. 2(b). Thereby the structure of the stamp 28 is transferred onto the photoresist layer 26. By means of UV-irradiation with light of about 350 to 450 nanometers during this step according to FIG. 2(b) the photoresist layer 26 is cured. After removing the stamp 28 according to FIG. 2(c) a substrate 24 with the nanostructured photoresist layer 26 remains at its surface.

Subsequently a further treatment by means of etching (dry etching) is performed, subsequently a two-dimensional coating with the desired metal layer, e.g. silver, and finally the removal of the photoresist layer. A nanostructured layer 20 remains with the discrete antenna elements 22 in the desired arrangement, with the desired distance to the absorber layer 12. Depending on the process conduct during etching, during the coating, and depending on the depth of the applied imprintings with the stamp into the photoresist layer, the nanostructured layer can be generated with the desired design parameters.

Depending on the height of the individual antenna elements 22 these either protrude from the AR-layer 16 upwardly or are fully received therein. As a final step then the application of a protective layer onto the surface is performed, normally using silicon dioxide.

In the above description the explanation of the contact fingers on the front side of the solar cell was omitted, since these are generated in the usual way by means of the respective manufacturing method of the solar cell 10.

The invention is not directed to the preparation method for the nanostructured layer 20 as such, but is substantially directed to the structure, the configuration and design of the nanostructured layer.

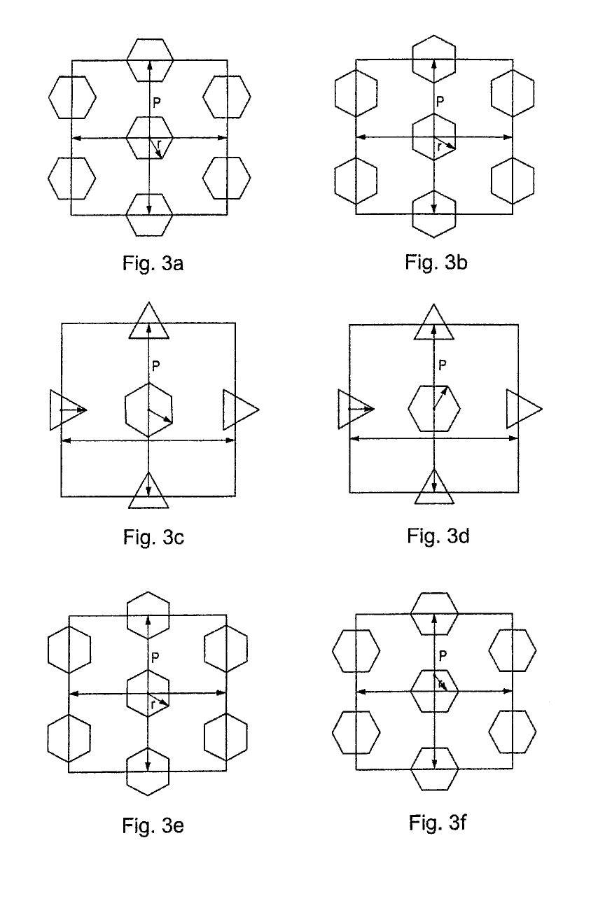

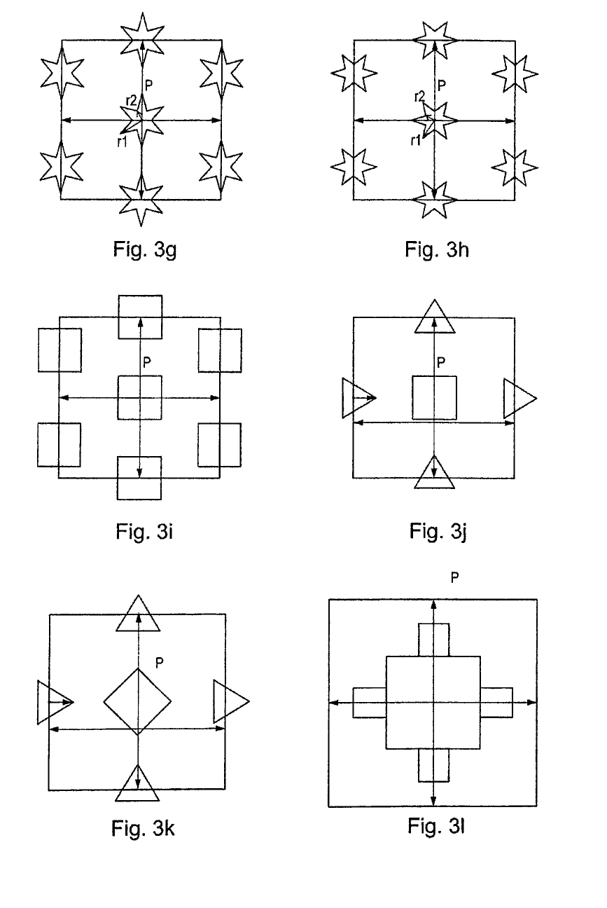

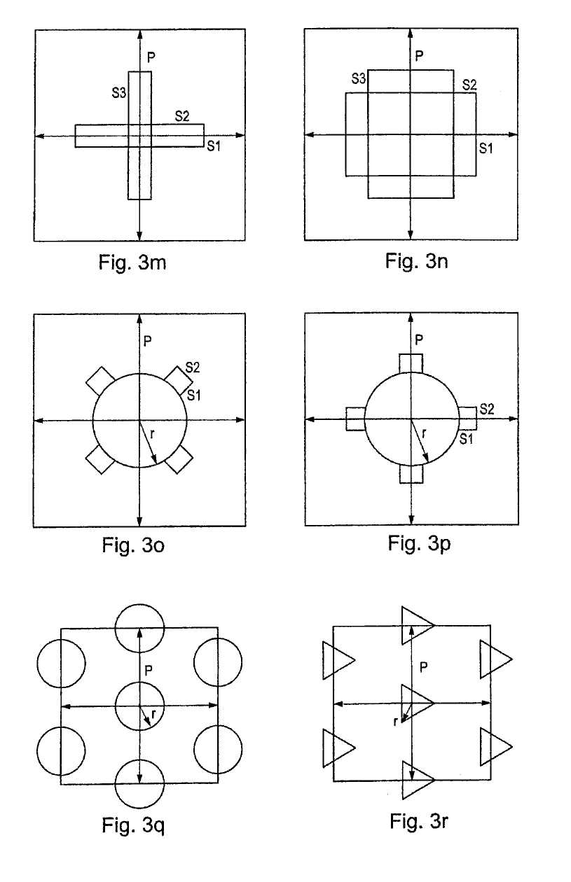

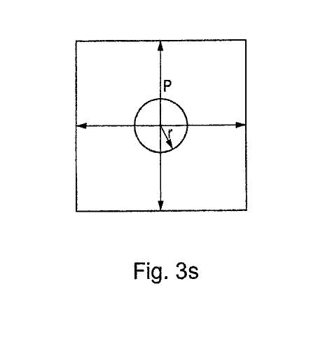

In FIGS. 3a to 3s a sequence of design variants of antenna elements 22 is depicted. Always the top view of one unit cell (period P) is shown.

It should be noted that in all described cases the respective antenna elements extend straight in the direction of the height, i.e. that they are configured as straight cylinders or prisms, respectively.

In FIGS. 3a and 3b hexagonal configurations of hexagonal antenna elements are shown. According to FIG. 3a the side faces are parallel to each other, while according to FIG. 3b the corners point to each other.

In FIGS. 3c and 3d combinations of a hexagonal antenna element in the center together with a triangle each in orthogonal configuration is shown. According to FIG. 3c the tip of the hexagon points towards the triangles, while according to FIG. 3d the side faces of a hexagon point towards the triangles.

FIGS. 3e and 3f correspond to FIGS. 3b and 3a, respectively.

In FIGS. 3g and 3h star-shaped antenna elements are shown, wherein FIG. 3g shows a hexagonal configuration, wherein the tip of the star-shaped antenna elements point towards each other. By contrast according to FIG. 3h the sides of the star-shaped antenna elements point to each other.

FIG. 3i shows a hexagonal configuration of quadratic antenna elements.

In FIGS. 3j and 3k combinations of a square and of triangles are shown, each with a square in the center and triangles on the side faces in orthogonal configuration. According to FIG. 3j the square is arranged with its side faces in parallel to the unit cell, while according to FIG. 3k the square was turned by 45°, so that the tips point towards the triangles.

In FIGS. 3l to 3p different cross structures are shown. These are each orthogonal configurations. According to FIG. 3l in the center there is a large square, wherein onto the side faces of the large square a small square each is applied in symmetrical configuration.

FIG. 3m shows a cross structure consisting of two bars crossed with each other.

FIG. 3n shows a cross structure of a large square, with small squares cut out at each corner.

FIG. 3o shows a cross structure with a central circle onto which in angle distances of 90° to each other small squares are applied to the outer side. According to FIG. 3o the squares are turned by 45° and thus point towards the corners of the unit cell. According to FIG. 3p the applied squares point parallel to the side face of the unit cell.

FIG. 3q shows a hexagonal configuration of cylinders.

FIG. 3r shows a hexagonal configuration of equilateral triangles.

FIG. 3s shows a cylinder in orthogonal configuration.

The used design parameters are summarized in Table 1. Herein always reference is made to the respective Figure.

TABLE 1

| | Hexagon side faces are parallel to each other | |
|---|---|---|
| Series 1: | (FIG. 3a) | |
| Configuration: | Hexagon (regular) | |
| Period (P): | 460 | nm |
| Radius (r): | 125 | nm |
| Distance (d): | 9 | nm |
| Material: | Silver (Ag) | |
| Varied: | | |
| Height (h) of 36 nm to 90 nm | | |
| (36, 50, 64, 70, 80, 90 nm) | | |
| | Hexagon corners point to each other | |
| Series 2: | (FIG. 3b) | |
| Configuration: | Hexagonal | |
| Form: | Hexagon (regular) | |
| Period (P): | 460 | nm |
| Radius (r): | 125 | nm |
| Distance (d): | 9 | nm |
| Material: | Silver (Ag) | |
| Varied: | | |
| Height (h) in structure of 36 nm to 90 nm | | |
| (36, 50, 64, 70, 80, 90 nm) | | |
| Series 3: | Hexagon and triangle (FIG. 3c) | |
| Configuration: | Orthogonal | |
| Form: | Hexagon and triangle | |
| Period (P): | 300 nm und 600 nm | |
| Radius hexagon: | 125.0 | nm |
| Radius triangle: | 72.5 | nm |
| Height (h): | 50.0 | nm |
| Distance (d): | 9.0 | nm |
| Material: | Silver (Ag) | |
| Series 3: | Hexagon (rotated) and triangle (FIG. 3d) | |
| Configuration: | Orthogonal | |
| Form: | Hexagon and triangle | |
| Period (P): | 300 nm and 600 nm | |
| Radius hexagon: | 125.0 | nm |
| Radius triangle: | 72.5 | nm |
| Height (h): | 50.0 | nm |
| Distance (d): | 9.0 | nm |
| Material: | Silver (Ag) | |
| | Hexagon with smaller radius than at | |
| | series, 2 corners point to each other | |
| Series 4: | (FIG. 3e) | |
| Configuration: | Hexagonal | |
| Form: | Hexagon (regular) | |
| Period (P): | of 260 to 460 nm | |
| Radius (r): | 62.5 | nm |
| Distance (d): | 9.0 | nm |
| Material: | Silver (Ag) | |
| Varied: | | |
| Height (h) in structure of 36 nm to 109 nm | | |
| (36, 50, 64, 70, 80, 109 nm) | | |
| | Hexagon with smaller radius than series 2, | |
| | side faces are arranged parallel to each other | |
| Series 5: | (FIG. 3f) | |
| Configuration: | Hexagonal | |
| Form: | Hexagon (regular) | |
| Period (P): | of 260 to 460 nm | |
| Radius (r): | 62.5 | nm |
| Distance (d): | 9.0 | nm |
| Material: | Silver (Ag) | |
| Varied: | | |
| Height (h) in structure of 36 nm to 100 nm | | |
| (36, 50, 64, 70, 80, 100 nm) | | |
| | Star (6 tips), corners point to each other | |
| Series 6: | (FIG. 3g) | |
| Configuration: | Hexagonal | |
| Form: | Hexagon (regular) | |
| Period (P): | of 265.5 to 460 nm | |
| Radius (r): | 125 nm (r1), 62.5 nm (r2) | |
| Distance (d): | 9 | nm |
| Material: | Silver (Ag) | |
| Varied: | | |
| Height (h) of 36 nm to 64 nm | | |
| (36, 50, 64 nm) | | |
| | Star (6 tips), side faces point to each other | |
| Series 7: | (FIG. 3h) | |
| Configuration: | Hexagonal | |
| Form: | Hexagon (regular) | |
| Period (P): | of 265.5 to 460 nm | |
| Radius (r): | 125 nm (r1), 62.5 nm (r2) | |
| Distance (d): | 9 | nm |
| Material: | Silver (Ag) | |
| Varied: | | |
| Height (h) of 36 nm to 64 nm | | |
| (36, 50, 64 nm) | | |
| | Square side faces are parallel to each other | |
| Series 8: | (FIG. 3i) | |
| Configuration: | Hexagonal | |
| Form: | Square | |
| Period (P): | 262.5 to 400 nm | |
| Distance (d): | 9 | nm |
| Material: | Silver (Ag) | |
| Varied: | | |
| Edge length: 88 nm to 250 nm | | |
| (88, 125, 177, 250 nm) | | |
| Height (h) of 36 nm to 110 nm | | |
| (36, 50, 60, 64, 70, 80, 90, 100, 110 nm) | | |
| Series 9: | Square and triangle (FIG. 3j) | |
| Configuration: | Orthogonal | |
| Form: | Square and triangle | |
| Period (P): | 380 and 520 nm | |
| Edge length: | 177.0 | nm |
| Radius triangle: | 72.5 | nm |
| Height (h): | 50.0 | nm |
| Distance (d): | 9.0 | nm |
| Material: | Silver (Ag) | |
| Series 10: | Square (rotated) and triangle (FIG. 3k) | |
| Configuration: | Orthogonal | |
| Form: | Square and triangle | |
| Period (P): | 380 nm and 520 nm | |
| Edge length: | 177.0 | nm |
| Radius triangle: | 72.5 | nm |
| Height (h): | 50.0 | nm |
| Distance (d): | 9.0 | nm |
| Material: | Silver (Ag) | |
| Series 11: | Cross structure (FIG. 3l) | |
| Configuration: | Orthogonal | |
| Form: | Square | |
| Period (P): | 525 | nm |
| Distance (d): | 9.0 | nm |
| Material: | Silver (Ag) | |
| Edge length small squares: | 50 | nm |
| Edge length large square: | 150 | nm |
| Varied: | | |
| Height (h) of 36 nm to 100 nm | | |
| (36, 50, 60, 70, 80, 90, 100 nm) | | |
| Series 12: | Cross structure (FIG. 3m) | |
| Configuration: | Orthogonal | |
| Form: | Rectangle | |
| Period (P): | 520 | nm |
| Distance (d): | 9 | nm |
| Material: | Silver (Ag) | |
| S1: | 63.0 | nm |
| S2: | 94.5 | nm |
| S3: | 94.5 | nm |
| Varied: | | |
| Height (h) of 36 nm to 64 nm | | |
| (36, 50, 64 nm) | | |
| Series 13: | Cross structure(FIG. 3n) | |
| Configuration: | Orthogonal | |
| Form: | Rectangle | |
| Period (P): | 520 | nm |
| Distance (d): | 9 | nm |
| Material: | Silver (Ag) | |
| S1: | 63.0 | nm |
| S2: | 94.5 | nm |
| S3: | 94.5 | nm |
| Varied: | | |
| Height (h) of 36 nm to 64 nm | | |
| (36, 50, 64 nm) | | |
| Series 14: | Cross structure (FIG. 3o) | |
| Configuration: | Orthogonal | |
| Form: | Rectangle, circle | |
| Period (P): | 500 | nm |
| Distance (d): | 9 | nm |
| Material: | Silver (Ag) | |
| S1: | 50 | nm |
| S2: | 50 | nm |
| r: | 123 | nm |
| Varied: | | |
| Height (h) of 36 nm to 100 nm | | |
| (36, 50, 64, 80, 90, 100 nm) | | |
| Series 15: | Cross structure (FIG. 3p) | |
| Configuration: | Orthogonal | |
| Form: | Rectangle, circle | |
| Period (P): | 520 | nm |
| Distance (d): | 9 | nm |
| Material: | Silver (Ag) | |
| S1: | 48 | nm |
| S2: | 50 | nm |
| r: | 125 | nm |
| Varied: | | |
| Height (h) of 36 nm to 100 nm | | |
| (36, 50, 64, 80, 90, 100 nm) | | |
| Series 16: | Cylinder (FIG. 3q) | |
| Configuration: | Hexagonal | |
| Form: | Cylinder | |
| Period (P): | 400 | nm |
| Radius (r): | 125 | nm |
| Height (h): | 40 | nm |
| Material: | Silver (Ag) | |
| Varied: | | |
| Distance (d) of 6 nm to 17 nm | | |
| (6, 7, 8, 9, 10, 11, 12, 15, 16, 17 nm) | | |
| Series 17: | Triangle (FIG. 3r) | |
| Configuration: | Hexagonal | |
| Form: | Triangle (equilateral) | |
| Period (P): | 520.0 | nm |
| Radius (r): | 145 nm and 72.5 nm | |
| Distance (d): | 9 | nm |
| Material: | Silver (Ag) | |
| Varied: | | |
| Height (h) of 22 nm to 100 nm | | |
| (22, 36, 50, 60, 70, 100 nm) | | |
| Series 18: | Cylinder (FIG. 3s) | |
| Configuration: | Orthogonal | |
| Form: | Cylinder | |
| Period (P): | 525 | nm |
| Radius (r): | 125 | nm |
| Height (h): | 50 | nm |
| Material: | Silver (Ag) | |
| Varied: | | |
| Distance (d) of 6 nm to 17 nm | | |
| (6, 7, 8, 9, 10, 11, 12, 15, 16, 17 nm) | | |
| Series 19: | Cylinder (FIG. 3s) | |
| Configuration: | Orthogonal | |
| Form: | Cylinder | |
| Period (P): | 525 | nm |
| Radius (r): | 125 | nm |
| Height (h): | 50 | nm |
| Coated surface: | Top/bottom | |
| Thickness of layer: | 10 | nm |
| Material: | Silver (Ag) | |
| Distance (d): | 9 | nm |
| Varied: | | |
| Dielectric with refraction index: n = 1.3 to 1.9 | | |
| (n = 1.3, 1.4, 1.6, 1.7, 1.8, 1.9) | | |
| as well as combinations with silicon dioxide | | |
| (SiO₂) or silicon nitride (Si₃N₄) | | |
| Series 20: | Cylinder (FIG. 3s) | |
| Configuration: | Orthogonal | |
| Form: | Cylinder | |
| Period (P): | 525 | nm |
| Radius (r): | 125 | nm |
| Height (h): | 50 | nm |
| Material: | Silver (Ag) | |
| Distance (d): | 9 | nm |
| Coated surface: | Up | |
| Material: | Copper, gold | |
| Varied: | | |
| Thickness of layer: 5 nm to 10 nm | | |
| (5, 6, 7, 8, 9, 10 nm) | | |
| Series 21: | Cylinder (FIG. 3s) | |
| Configuration: | Orthogonal | |
| Form: | Cylinder | |
| Period (P): | 525 | nm |
| Radius (r): | 125 | nm |
| Height (h): | 50 | nm |
| Material: | Silver (Ag) | |
| Distance (d): | 9 | nm |
| Coated Surface: | Up | |
| Material: | Gold, copper | |
| Thickness of layer: | 7 | nm |
| Varied: | | |
| Distance (d) of gold/copper layer from | | |
| the cylinder top side: 6 nm to 16 nm | | |
| (6, 8, 10, 12, 14, 16 nm) | | |
| | Cylinder with additional | |
| | disks on top o feach other | |
| Series 22: | (FIG. 3s) | |
| Configuration: | Orthogonal | |
| Form: | Cylinder | |
| Period (P): | 525 | nm |
| Radius (r): | 125 | nm |
| Height (h): | 50 | nm |
| Material: | Silver (Ag) | |
| Distance (d): | 9 | nm |
| Two disks (cylinders) | | |
| Material: | Silver (Ag) | |
| Thickness of layer: | 6 nm and 10 nm | |
| Varied: | | |
| Distance (d) of 1. disk from cylinder top | | |
| side of 40 nm and 44 nm and distance (d) | | |
| of 2. disk of the 2. disk of 10 nm and | | |
| 28 nm (10, 19, 28 nm) | | |
| Series 23: | Cylinder (FIG. 3s) | |
| Configuration: | Orthogonal | |
| Form: | Cylinder | |
| Radius (r): | 125 | nm |
| Height (h): | 70 | nm |
| Material: | Silver (Ag) | |
| Distance (d): | 9 | nm |
| Varied: | | |
| Period of 375 nm to 600 nm | | |
| (375, 400, 425, 450, 475, 500, | | |
| 525, 550, 575, 600 nm) | | |
| Series 24: | Cylinder (FIG. 3s) | |
| Configuration: | Orthogonal | |
| Form: | Cylinder | |
| Period (P): | 525 | nm |
| Radius (r): | 125 | nm |
| Material: | Silver (Ag) | |
| Distance (d): | 9 | nm |
| Varied: | | |
| Height (h) of 20 nm to 109 nm | | |
| (20, 30, 40, 50, 60, 70, 80, | | |
| 90, 100, 109 nm) | | |
| Series 25: | Cylinder (FIG. 3s) | |
| Configuration: | Orthogonal | |
| Form: | Cylinder | |
| Period (P): | 525 | nm |
| Height (h): | 70 | nm |
| Material: | Silver (Ag) | |
| Distance (d): | 9 | nm |
| Varied: | | |
| Radius (r) of 70 nm to 160 nm | | |
| (70, 80, 90, 100, 110, 115, 120, | | |
| 125, 135, 140, 150, 160 nm) | | |
| Series 26: | Cylinder (FIG. 3s) | |
| Configuration: | Orthogonal | |
| Form: | Cylinder | |
| Radius (r): | 95 | nm |
| Height (h): | 70 | nm |
| Material: | Silver (Ag) | |
| Distance (d): | 9 | nm |
| Varied: | | |
| Period (P) of 375 nm to 600 nm | | |
| (375, 400, 425, 450, 460, 464.75, | | |
| 470, 475, 500, 525, 550, 575, 600 nm) | | |
| Series 27: | Cylinder (FIG. 3s) | |
| Configuration: | Orthogonal | |
| Form: | Cylinder | |
| Period (P): | 464.75 | nm |
| Radius (r): | 95 | nm |
| Material: | Silver (Ag) | |
| Distance (d): | 9 | nm |
| Varied: | | |
| Height (h) of 20 nm to 109 nm | | |
| (20, 30, 40, 50, 60, 70, 80, | | |
| 90, 100, 109 nm) | | |
| Series 28: | Cylinder (FIG. 3s) | |
| Configuration: | Orthogonal | |
| Form: | Cylinder | |
| Period (P): | 464.75 | nm |
| Height (h): | 70 | nm |
| Material: | Silver (Ag) | |
| Distance (d): | 9 | nm |

Varied:
Radius (r) of 50 nm to 120 nm
(50, 70, 80, 85, 90, 100, 110, 120 nm)

In Table 1 further simulation results are summarized in additional series 19 to 28. They relate to the respective cylinder with orthogonal configuration according to FIG. 3s.

Selected simulation results referring to the computed absorption increases g depending from the wavelength are summarized in FIGS. 4a to 4l. As can be seen from the individual representation, partially strong absorption increases in selected wavelength ranges result. The characteristics of the plasmons within the anti-reflection layers thus not only allow for an improved photon-management, but also by using specific design parameters an optical filter function or a signal attenuation, respectively, and a simultaneously amplification of specific wavelength ranges can be reached. Thus the nano antenna element 22 can be varied with respect to their design parameters to effect specific characteristics with respect to optical sensors.

FIG. 4a shows simulation results with respect to the cross structure according to series 11, see Table 1. The representation of the absorption increase depending form the wavelength shows two strong peaks at about 1050 nanometers and 725 nanometers with an amplification of up to 6-fold. The remaining frequency range remains unaffected or is only relatively weakly amplified, respectively, up to a range of about 550 nanometers. The position of the peaks and their height, respectively, can be influenced by the design parameters.

FIG. 4b shows simulation results with respect to the cross structure according to series 12 and 13. It can be seen that two strong peaks at 1050 and 825 nanometers are present with an amplification up to 16-fold. The remaining frequency region remains unaffected or is only relatively weakly amplified. The position of the peaks and their height, respectively, can be influenced by the design parameters.

FIG. 4c shows simulation results for the cross structure according to series 16. Two strong peaks at about 1050 nanometers and about 725 nanometers with an amplification up to 6-fold can be seen. The remaining frequency region remains unaffected or is only relatively weakly amplified, respectively, until a region of about 550 nanometers. The position of the peaks or their height, respectively, can be influenced by the design parameters.

FIG. 4d shows simulation results for the cross structure according to series 15. It can be seen that two very strong peaks at about 1000 nanometers and about 750 nanometers are present with an amplification up to 4-fold. The remaining frequency region remains unaffected or is only relatively weakly amplified, respectively, until a region of about 550 nanometers. The position of the peaks or their height, respectively, can be influenced by the design parameters.

FIG. 4e shows simulation results with respect to the triangle structure according to series 17. It can be seen that a very strong peak at about 1050 nanometers with an amplification up to 19-fold results. The remaining frequency region remains unaffected or is only relatively weakly amplified, respectively. The position of the peaks and their height, respectively, can be influenced by the design parameters.

FIG. 4f shows simulation results with respect to the star structure according to series 6 and 7. In can be seen that a very strong peak at about 825 nanometers and with an amplification up to 3.3-fold results. The remaining frequency region remains unaffected or is only relatively weakly amplified, respectively. The position of the peaks and their height, respectively, can be influenced by the design parameters.

FIGS. 4g to l show simulation results for the square structure according to series 8. Three strong peaks at about 1100 nanometers, 850 nanometers, and 725 nanometers with an amplification up to 7-fold can be seen. The remaining frequency region remains unaffected or is amplified only relatively weakly, respectively. The position of the peaks and their height, respectively, can be influenced by the design parameters.

From the simulation results in FIGS. 4a to 4l it can be seen in total that by a variation of the various design parameters the absorption characteristics can be influenced specifically for amplifying specific frequency regions, which is advantageous for an application as a sensor.

For an ultra-thin layer solar cell with an absorption layer of a thickness of 150 nanometers of silicon, a back contact of silver with a thickness of about 200 nanometers, an anti-reflection layer 16 with a thickness of about 45 nanometers of Si₃N₄ and a protective layer of silicon dioxide with a thickness of about 64 nanometers the following parameters were determined as optimal design parameters:

The antenna elements 22 are cylindrical in orthogonal configuration with a period of 525 nanometers. The radius is 125 nanometers, and the height h 70 nanometers. The distance d from the absorber layer 12 is 9 nanometers.

As optimal parameters for a standard thick-layer solar cell of a thickness of about 180 to 200 micrometers were determined:

Cylindrical shape of the antenna elements in orthogonal configuration with a period of 464.75 nanometers. The radius of the cylinders is 95 nanometers and the height h 70 nanometers. The distance d from the absorber layer 12 is 9 nanometers.

With the thick-layer HIT-cells the period is optimally 490 nanometers.

1. A photovoltaic cell, comprising:
an absorber layer;
an anti-reflection layer is arranged in front of said absorber layer, said anti-reflection layer comprising:
a nanostructured layer having periodically arranged antenna elements made of an electrically conductive material, said antenna elements being arranged in a regular pattern at a distance of 1 to 50 nanometers from said absorber layer and being is at least partially received within said anti-reflection layer;
wherein said nanostructured layer together with a back contact of said photovoltaic cell forms an optical resonator;
wherein said antenna elements are arranged at a distance of 2 to 20 nanometers from said absorber layer;
wherein said antenna elements are arranged periodically with respect to each other at distances of 200 to 800 nanometers; and
wherein said antenna elements have a height of 10 to 200 nanometers.

2. A photovoltaic cell, comprising:
an absorber layer;
an anti-reflection layer is arranged in front of said absorber layer, said anti-reflection layer comprising:
a nanostructured layer having periodically arranged antenna elements made of an electrically conductive material, said antenna elements being arranged at a distance of 1 to 50 nanometers from said absorber layer and being is at least partially received within said anti-reflection layer.

3. The photovoltaic cell of claim 2, wherein said nanostructured layer together with a back contact of said photovoltaic cell forms an optical resonator.

4. The photovoltaic cell of claim 2, wherein said nanostructured layer is arranged at a distance of 2 to 20 nanometers from said absorber layer.

5. The photovoltaic cell of any of claim 2, wherein said antenna elements are arranged periodically with respect to each other at distances of 200 to 800 nanometers.

6. The photovoltaic cell of claim 2, wherein said antenna elements have a height of 10 to 200 nanometers.

7. The photovoltaic cell of claim 2, wherein said antenna elements have a maximum extension in lateral direction of 20 to 400 nanometers.

8. The photovoltaic cell of claim 2, wherein said antenna elements have a minimum extension in lateral direction of 25 nanometers.

9. The photovoltaic cell of claim 2, wherein said nanostructured layer consists of a material selected form the group consisting of SiOxNy, titanium oxide, and ITO.

10. The photovoltaic cell of claim 2, wherein said nanostructured layer consists of antenna elements selected form the group consisting of identical antenna elements, antenna elements of different shapes, and antenna elements of different sizes being combined with each other in a regular pattern.

11. The photovoltaic cell of claim 2, wherein said antenna elements are configured as cylinders or as straight prisms extending perpendicularly to a main direction of extension of said photovoltaic cell.

12. The photovoltaic cell of claim 2, wherein said antenna elements consist of a metal which is selected from the group consisting of silver, copper, aluminum, gold, and alloys thereof.

13. The photovoltaic cell of claim 2, wherein said antenna elements consist of a metal which is selected from the group consisting of silver, copper, aluminum, gold and alloys thereof, and wherein at least one side of said antenna elements facing said absorber or facing away from said absorber is coated with a different material being selected from the group consisting of silver, copper, aluminum, gold, and alloys thereof.

14. The photovoltaic cell of claim 2, being configured as a solar cell, wherein said nanostructured layer consists of straight cylinders.

15. The solar cell of claim 14, wherein said nanostructured layer consists of cylinders with a diameter of 150 to 250 nanometers.

16. The photovoltaic cell of claim 2, which is configured as a standard thick-layer solar cell with a thickness of up to 200 micrometers, wherein said cylinders of said nanostructured layer have a diameter of 185 to 195 nanometers, a height of 68 to 72 nanometers, said cylinders being arranged in an orthogonal pattern at a distance to said absorber layer of 8.5 to 9.5 nanometers, and at a distance of 460 to 470 nanometers with respect to each other.

17. The solar cell of claim 2, being configured as a HIT thick-layer solar cell with a thickness if up to 200 micrometers, wherein said cylinders of said nanostructured layer have a diameter of about 185 to 195 nanometers, a height of 68 to 72 nanometers, being arranged at a distance to said absorber layer of 8.5 to 9.5 nanometers, and being arranged in an orthogonal pattern with respect to each other at a distance of 485 to 495 nanometers.

18. The solar cell of claim 2, being configured as a ultra-thin layer solar cell, wherein said nanostructured layer consists of cylinders with a diameter of 200 to 300 nanometers, said cylinders having a height of 50 to 90 nanometers and being arranged in an orthogonal pattern at a distance of 400 to 600 nanometers form each other and at a distance to said absorber layer of 5 to 13 nanometers.

19. A method of preparing a photovoltaic cell, wherein said photovoltaic cell is made with an absorber and an anti-reflection layer arranged there above, wherein said anti-reflection layer is prepared with a nanostructured layer with periodically arranged antenna elements of an electrically conductive material with a distance of 1 to 50 nanometers to said absorber surface.

20. The method of preparing a photovoltaic cell of claim 19, wherein the preparation of said nanostructured layer after said application of said absorber layer and a protective layer comprises at least the following steps:
applying a photoresist layer onto said protective layer;
embossing the photoresist layer by means of a nanostructured stamp;
developing the photoresist layer by irradiating by means of UV light for generating a nanostructured photoresist layer;
etching for generating recesses;
two-dimensional coating of the nanostructured layer within electrically conductive material:
removing of the photoresist layer.
